(19) United States
(12) Patent Application Publication
(10) Pub. No.: US 2019/0100851 A1
(43) Pub. Date: Apr. 4, 2019

(54) Thermochemical Gas Sensor Using Thermoelectric Thin Film And Method Of Manufacturing The Same

(71) Applicant: Industry-University Cooperation Foundation Hanyang University Erica Campus, Gyeonggi-do (KR)

(72) Inventors: Yong Ho Choa, Gyeonggi-do (KR); Seil Kim, Gyeonggi-do (KR); Yoseb Song, Gyeonggi-do (KR)

(73) Assignee: Industry-University Cooperation Foundation Hanyang University Erica Campus, Gyeonggi-do (KR)

(21) Appl. No.: 16/086,655

(22) PCT Filed: Jan. 24, 2017
(86) PCT No.: PCT/KR2017/000838

§ 371 Date: Sep. 20, 2018

(30) Foreign Application Priority Data
Mar. 31, 2016 (KR) 10-2016-0038844
Dec. 14, 2016 (KR) 10-2016-0170070

(51) Int. Cl. C25D 7/12; C25D 11/32; C25D 17/00; G01N 25/32; H01L 35/12

(52) U.S. Cl. CPC C25D 7/123; C25D 11/32; H01L 35/12; G01N 25/32; C25D 17/00

(57) ABSTRACT

The present invention relates to a thermochemical gas sensor including a substrate provided with an insulating layer; a seed layer provided on the insulating layer; a thermoelectric thin film provided on the seed layer; an electrode provided on the thermoelectric thin film; a catalyst layer provided on the electrode and causing exothermic reaction when in contact with gas to be sensed; and an electrode wire electrically connected to the electrode, wherein the thermoelectric thin film is formed of a material including a chalcogenide, wherein the chalcogenide includes one or more chalcogens selected from the group consisting of selenium (Se) and tellurium (Te). The thermochemical gas sensor according to the present invention can be miniaturized and sense gases at various concentrations due to being based on a thermoelectric thin film, does not undergo physical/chemical changes, such as phase change of a thermoelectric thin film, even if repeatedly exposed to gas, and can sense various desired gas types using changes in a catalyst reacting selectively with gases to be sensed.

### TECHNICAL FIELD

The present invention relates to a thermoelectric thin film-based thermochemical gas sensor and a method of manufacturing the same, and more particularly, to a thermochemical gas sensor that is capable of being miniaturized and sensing gases at various concentrations due to being based on a thermoelectric thin film, does not undergo physical/chemical changes, such as phase change of a thermoelectric thin film, even if repeatedly exposed to gas, and is capable of sensing various desired gas types using changes in a catalyst reacting selectively with gases to be sensed, and a method of manufacturing the same.

### BACKGROUND ART

Although hydrogen gas is attracting attention as a future clean fuel, it requires more precise and complete sensing than other combustible gases, upon application to sensors, due to inherent properties thereof.

In general, hydrogen gas has a wide explosive concentration range of 4 to 75%. Accordingly, a sensor for sensing hydrogen gas should be able to sense gas at a low concentration and in a wide concentration range, should not be affected by gases, vapor (including humidity), temperature, etc. except for hydrogen gas, and should meet conditions such as high sensing accuracy and miniaturization for practical use. Research into various kinds of hydrogen sensors having the characteristics is being actively conducted. As examples of hydrogen sensor types being currently, actively studied, there are a contact combustion-type hydrogen sensor, a hot wire-type hydrogen sensor, a thermoelectric hydrogen sensor, and a semiconductive hydrogen sensor, an electrochemical hydrogen sensor, and a metal absorption-type hydrogen sensor using the property that the electron density of a particle surface is changed when hydrogen is adsorbed thereto and thus resistance is changed, etc.

The most important factor in hydrogen sensing is that it should be possible to sense hydrogen at room temperature. In addition, to secure price competitiveness of future devices, high-vacuum and high-temperature processes with high process costs should be excluded and technology for synthesizing materials at room temperature should be developed.

In the case of a SiGe-based thin film hydrogen sensor, since the material itself has a high Seebeck coefficient at high temperature, a platinum (Pt) heater should be used so that operation is performed at high temperature when the SiGe-based thin film hydrogen sensor is used as an actual sensor. In the case of a palladium-based hydrogen sensor generally used for sensing hydrogen, there are difficulties in manufacturing the sensor at low cost because expensive palladium nanoparticles and nanowires are used and high temperature and high vacuum conditions are required in process of manufacturing the sensor and materials constituting the same.

Most research into thermoelectric material-based hydrogen sensors has focused on a palladium/platinum gate field effect transistor (FET). In addition, there is a problem that sensing ability is decreased at a high concentration range. Further, when a palladium-based sensor is repeatedly exposed to hydrogen gas, rapid phase changes may occur, which cause performance deterioration. Therefore, there is a need for research into a sensor capable of sensing hydrogen gas in a wider concentration range.

In addition, since development of and demand for hydrogen fuel cells, which are attracting attention as future clean energy, are increasing, there is a need for research into securing the stability of fuel cells and producing energy by using waste heat with a thermoelectric material in the automotive field. In addition, there is a need for development of a hydrogen sensor suitable for hydrogen batteries because the hydrogen batteries are also used in aerospace, such as in satellites and space shuttles. Further, there is a need for research into miniaturizing, increasing sensitivity of, and mass-producing a hydrogen sensor in connection with a microelectromechanical system (MEMS) as one technology for manufacturing ultra-small circuits.

### RELATED ART DOCUMENT

### Patent Document

Korean Patent No. 10-0929025

### DISCLOSURE

### Technical Problem

In accordance with an aspect of the present invention, the above and other objects can be accomplished by the provision of a thermochemical gas sensor that is capable of being miniaturized and sensing gases at various concentrations due to being based on a thermoelectric thin film, does not undergo physical/chemical changes, such as phase change of a thermoelectric thin film, even if repeatedly exposed to gas, and is capable of sensing various desired gas types using changes in a catalyst reacting selectively with gases to be sensed.

In accordance with another aspect of the present invention, there is provided a method of manufacturing a thermochemical gas sensor that is capable of synthesizing a thermoelectric thin film having a desired type and composition to a uniform thickness in an easy manner at low process costs using a wet electrolytic deposition method, allowing manufacture of a gas sensor under room temperature and atmospheric pressure conditions excluding high vacuum and temperature processes having high process costs, minimizing the amounts of materials used in each device to secure price competitiveness, synthesizing a thermoelectric thin film to a desired thickness of several microns to allow miniaturization of a sensor, being manufactured based on a thermoelectric thin film to provide a wide concentration range for sensing gas, preventing physical/chemical changes such as phase change of a thermoelectric thin film even if repeatedly exposed to gas, and sensing various gas types using changes in a catalyst selectively reacting with gas to be sensed.

### Technical Solution

In accordance with an aspect of the present invention, the above and other objects can be accomplished by the provision of a thermochemical gas sensor including a substrate provided with an insulating layer; a seed layer provided on the insulating layer; a thermoelectric thin film provided on the seed layer; an electrode provided on the thermoelectric thin film; a catalyst layer provided on the electrode and causing an exothermic reaction when in contact with gas to be sensed; and an electrode wire electrically connected to the electrode, wherein the thermoelectric thin film is formed of a material including a chalcogenide, wherein the chalcogenide includes one or more chalcogens selected from the group consisting of selenium (Se) and tellurium (Te).

A thermal grease layer for transferring heat may be provided between the electrode and the catalyst layer.

The thermal grease layer may include one or more thermally conductive materials selected from the group consisting of boron nitride (BN), graphene, carbon nanotubes, active carbon, and carbon black.

The substrate may include a silicon (Si) substrate.

The insulating layer may include a SiO₂ oxide film.

The seed layer preferably has a thickness of 10 to 1000 nm and may be formed of a material including one or more metal types selected from the group consisting of gold (Au), silver (Ag), and copper (Cu).

The catalyst layer may be formed of a composite of one or more materials selected from the group consisting of γ-alumina, graphene, carbon nanotubes, active carbon, and carbon black and a material including one or more metal types selected from the group consisting of platinum (Pt) and palladium (Pd).

The catalyst layer preferably has a thickness of 0.5 to 100 μm.

The chalcogenide may include one or more materials selected from the group consisting of BiₓSe_{y} (1.5≤x≤2.5, 2.4≤y≤3.6), SbₓSe_{y} (1.5≤x≤2.5, 2.4≤y≤3.6), (Bi₁₋ₘSbₘ)ₓSe_{y} (0<m<1, 1.5≤x≤2.5, 2.4≤y≤3.6), PbSe, CdSe, ZnSe, PbTeSe, BiₓTe_{y} (1.5≤x≤2.5, 2.4≤y≤3.6), SbₓTe_{y} (1.5≤x≤2.5, 2.4≤y≤3.6), (Bi₁₋ₘSbₘ)ₓTe_{y} (0<m<1, 1.523 x≤2.5, 2.4≤y≤3.6), PbTe, CdTe, ZnTe, La₃Te₄, AgSbTe₂, Ag₂Te, AgPb₁₈BiTe₂₀, (GeTe)ₓ(AgSbTe₂)₁₋ₓ, (x is a real number less than 1), AgₓPb₁₈SbTe₂₀ (x is a real number less than 1), AgₓPb_{22.5}SbTe₂₀ (x is a real number less than 1), SbₓTe₂₀ (x is a real number less than 1), and BiₓSb₂₋ₓTe₃ (x is a real number less than 2).

In accordance with another aspect of the present invention, there is provided a thermochemical gas sensor including a substrate provided with an insulating layer; seed layers provided on the insulating layer; a P-type thermoelectric thin film provided on the seed layers; an N-type thermoelectric thin film provided on the seed layers and spaced from the P-type thermoelectric thin film; electrodes provided on the P-type thermoelectric thin film and the N-type thermoelectric thin film; a catalyst layer provided on the electrodes and causing an exothermic reaction when in contact with gas to be sensed; and electrode wires electrically connected to the electrodes, wherein the P-type thermoelectric thin film and the N-type thermoelectric thin film are formed of a material including a chalcogenide, wherein the chalcogenide includes one or more chalcogens selected from the group consisting of selenium (Se) and tellurium (Te), and the P-type thermoelectric thin film is formed of a chalcogenide different from a chalcogenide forming the N-type thermoelectric thin film.

A thermal grease layer for transferring heat may be provided between the electrodes and the catalyst layer.

The thermal grease layer may include one or more thermally conductive materials selected from the group consisting of boron nitride (BN), graphene, carbon nanotubes, active carbon, and carbon black.

The substrate may include a silicon (Si) substrate.

The insulating layer may include a SiO₂ oxide film.

The seed layers preferably has a thickness of 10 to 1000 nm and may be formed of a material including one or more metal types selected from the group consisting of gold (Au), silver (Ag), and copper (Cu).

The catalyst layer may be formed of a composite of one or more materials selected from the group consisting of γ-alumina, graphene, carbon nanotubes, active carbon, and carbon black and a material including one or more metal types selected from the group consisting of platinum (Pt) and palladium (Pd).

The catalyst layer preferably has a thickness of 0.5 to 100 μm.

The chalcogenide may include one or more materials selected from the group consisting of BiₓSe_{y} (1.5≤x≤2.5, 2.4≤y≤3.6), SbₓSe_{y} (1.5≤x≤2.5, 2.4≤y≤3.6), (Bi₁₋ₘSbₘ)ₓSe_{y} (0<m<1, 1.5≤x≤2.5, 2.4≤y≤3.6), PbSe, CdSe, ZnSe, PbTeSe, BiₓTe_{y} (1.5≤x≤2.5, 2.4≤y≤3.6), SbₓTe_{y} (1.5≤x≤2.5, (Bi₁₋ₘSbₘ)ₓTe_{y} (0<m<1, 1.5≤x≤2.5, 2.4≤y≤3.6), PbTe, CdTe, ZnTe, La₃Te₄, AgSbTe₂, Ag₂Te, AgPb₁₈BiTe₂₀, (GeTe)ₓ(AgSbTe₂)₁₋ₓ, (x is a real number less than 1), AgₓPb₁₈SbTe₂₀ (x is a real number less than 1), AgₓPb_{22.5}SbTe₂₀ (x is a real number less than 1), SbₓTe₂₀ (x is a real number less than 1), and BiₓSb₂₋ₓTe₃ (x is a real number less than 2).

In accordance with another aspect of the present invention, there is provided a method of manufacturing a thermochemical gas sensor, the method including a step of preparing a substrate provided with an insulating layer; a step of forming a seed layer on the insulating layer; a step of forming a thermoelectric thin film on the seed layer using a wet electrolytic deposition method; a step of forming an electrode on the thermoelectric thin film; a step of forming an electrode wire electrically connected to the electrode; and a step of forming a catalyst layer, which causes an exothermic reaction when in contact with gas to be sensed, on the electrode, wherein the thermoelectric thin film is formed of a material including a chalcogenide, wherein the chalcogenide includes one or more chalcogens selected from the group consisting of selenium (Se) and tellurium (Te).

The method may further include a step of forming a thermal grease layer for transferring heat on the electrode before the step of forming the catalyst layer.

The thermal grease layer may include one or more thermally conductive materials selected from the group consisting of boron nitride (BN), graphene, carbon nanotubes, active carbon, and carbon black.

The substrate may include a silicon (Si) substrate.

The insulating layer may include a SiO₂ oxide film.

The seed layer has a thickness of 10 to 1000 nm and may be formed of a material including one or more metal types selected from the group consisting of gold (Au), silver (Ag), and copper (Cu).

The catalyst layer may be formed of a composite of one or more materials selected from the group consisting of γ-alumina, graphene, carbon nanotubes, active carbon, and carbon black and a material including one or more metal types selected from the group consisting of platinum (Pt) and palladium (Pd).

The catalyst layer preferably has a thickness of 0.5 to 100 μm.

The chalcogenide may include one or more materials selected from the group consisting of BiₓSe_{y} (1.5≤x≤2.5, 2.4≤y≤3.6), SbₓSe_{y} (1.5≤x≤2.5, 2.4≤y≤3.6), (Bi₁₋ₘSbₘ)ₓSe_{y} (0<m<1, 1.5≤x≤2.5, 2.4≤y≤3.6), PbSe, CdSe, ZnSe, PbTeSe, BiₓTe_{y} (1.5≤x≤2.5, 2.4≤y≤3.6), SbₓTe_{y} (1.5≤x≤2.5, 2.4≤y≤3.6), (Bi₁₋ₘSbₘ)ₓTe_{y} (0<m<1, 1.5≤x≤2.5, 2.4≤y≤3.6), PbTe, CdTe, ZnTe, La₃Te₄, AgSbTe₂, Ag₂Te, AgPb₁₈BiTe₂₀, (GeTe)ₓ(AgSbTe₂)₁₋ₓ, (x is a real number less than 1), AgₓPb₁₈SbTe₂₀ (x is a real number less than 1), AgₓPb_{22.5}SbTe₂₀ (x is a real number less than 1), SbₓTe₂₀ (x is a real number less than 1), and BiₓSb₂₋ₓTe₃ (x is a real number less than 2).

In accordance with yet another aspect of the present invention, there is provided a method of manufacturing a thermochemical gas sensor, the method including a step of preparing a substrate provided with an insulating layer; a step of forming seed layers on the insulating layer; a step of forming a P-type thermoelectric thin film and an N-type thermoelectric thin film to be spaced from each other on the seed layers using a wet electrolytic deposition method; a step of forming electrodes on the P-type thermoelectric thin film and the N-type thermoelectric thin film; a step of forming electrode wires electrically connected to the electrodes; and a step of forming a catalyst layer, which causes an exothermic reaction when in contact with gas to be sensed, on the electrodes, wherein the thermoelectric thin film is formed of a material including a chalcogenide, wherein the chalcogenide includes one or more chalcogens selected from the group consisting of selenium (Se) and tellurium (Te), and the P-type thermoelectric thin film is formed of a chalcogenide different from a chalcogenide forming the N-type thermoelectric thin film.

The method may further include a step of forming a thermal grease layer for transferring heat on the electrodes before the step of forming the catalyst layer.

The thermal grease layer may include one or more thermally conductive materials selected from the group consisting of boron nitride (BN), graphene, carbon nanotubes, active carbon, and carbon black.

The substrate may include a silicon (Si) substrate.

The insulating layer may include a SiO₂ oxide film.

The seed layers has a thickness of 10 to 1000 nm and may be formed of a material including one or more metal types selected from the group consisting of gold (Au), silver (Ag), and copper (Cu).

The catalyst layer may be formed of a composite of one or more materials selected from the group consisting of γ-alumina, graphene, carbon nanotubes, active carbon, and carbon black and a material including one or more metal types selected from the group consisting of platinum (Pt) and palladium (Pd).

The catalyst layer preferably has a thickness of 0.5 to 100 μm.

The chalcogenide may include one or more materials selected from the group consisting of BiₓSe_{y} (1.5≤x≤2.5, 2.4≤y≤3.6), SbₓSe_{y} (1.5≤x≤2.5, (Bi₁₋ₘSbₘ)ₓSe_{y} (0<m<1, 1.5≤x≤2.5, 2.4≤y≤3.6), PbSe, CdSe, ZnSe, PbTeSe, BiₓTe_{y} (1.5≤x≤2.5, 2.4≤y≤3.6), SbₓTe_{y} (1.5≤x≤2.5, 2.4≤y≤3.6), (Bi₁₋ₘSbₘ)ₓTe_{y} (0<m<1, 1.5≤x≤2.5, 2.4≤y≤3.6), PbTe, CdTe, ZnTe, La₃Te₄, AgSbTe₂, Ag₂Te, AgPb₁₈BiTe₂₀, (GeTe)ₓ(AgSbTe₂)₁₋ₓ (x is a real number less than 1), AgₓPb₁₈SbTe₂₀ (x is a real number less than 1), AgₓPb_{22.5}SbTe₂₀ (x is a real number less than 1), SbₓTe₂₀ (x is a real number less than 1), and BiₓSb₂₋ₓTe₃ (x is a real number less than 2).

### Advantageous Effects

A thermochemical gas sensor of the present invention can be miniaturized and sense gases at various concentrations due to being based on a thermoelectric thin film, does not undergo physical/chemical changes, such as phase change of a thermoelectric thin film, even if repeatedly exposed to gas, and can sense various desired gas types using changes in a catalyst reacting selectively with gases to be sensed.

In accordance with the present invention, a thermoelectric thin film having a desired type and composition can be synthesized to a uniform thickness in an easy method at less process costs using a wet electrolytic deposition method, a gas sensor can be manufactured under room temperature and atmospheric pressure conditions excluding high vacuum and temperature processes having high process costs, the amounts of materials used in each device can be minimized and thus price competitiveness can be secured, a thermoelectric thin film can be synthesized to a desired thickness and a several micron thickness to allow miniaturization of a sensor, and a sensor based on a thermoelectric thin film can be manufactured and thus a wide concentration range for sensing gas can be provided, physical/chemical changes such as phase change of a thermoelectric thin film is not caused even if repeatedly exposed to gas, and various gas types can sensed by using changes in a catalyst selectively reacting with gas to be sensed.

In accordance with the present invention, a thermoelectric thin film having a desired thickness and composition can be manufactured by controlling wet electrolytic deposition conditions such as an electrolyte and voltage.

In accordance with the present invention, a thermoelectric thin film exhibiting thermoelectric properties in a desired temperature range depending upon operation temperature can be easily synthesized, various desired gas types can be sensed using changes in a catalyst reacting selectively with gas to be sensed, and a method of evaluating a thermoelectric performance index with gas can be utilized using a technology of sensing changes in temperature and a minute electromotive force exhibited upon sensing of gas.

In addition, steady research into a thermoelectric hydrogen sensor having a multiple N-P junction structure in a narrow area and unique electrical and optical characteristics can provide a new possibility for the thermoelectric sensor market.

Further, application of a hydrogen sensor in connection with an MEMS technology, as one type of a technology of manufacturing an ultra-small circuit, can allow miniaturization, high sensitization, and mass production of a sensor, and miniaturization of the hydrogen sensor can allow application to the MEMS technology through the development of an integrated catalyst coating technology using inkjet printing, etc.

### DESCRIPTION OF DRAWINGS

FIGS. 1 to 6 illustrate a method of manufacturing a thermochemical gas sensor according to Example 1.

FIGS. 7 to 14 illustrate a method of manufacturing a thermochemical gas sensor according to Example 2.

FIG. 15 illustrates results of Bi³⁺ concentration-dependent reduction potentials measured using cyclic voltammetry.

FIG. 16 illustrates applied voltage-dependent X-ray diffraction (XRD) patterns of a BiₓTe_{y} thin film deposited by varying an applied voltage during wet electrolytic deposition.

FIG. 17 illustrates a field emission scanning electron microscope (FE-SEM) image of a BiₓTe_{y} thin film deposited by applying a voltage of 50 mV for one hour in a wet electrolytic deposition method.

FIG. 18 illustrates a FE-SEM image of a BiₓTe_{y} thin film deposited by applying a voltage of 0 mV for one hour in a wet electrolytic deposition method.

FIG. 19 illustrates a FE-SEM image of a BiₓTe_{y} thin film deposited by applying a voltage of −50 mV for one hour on a wafer in a wet electrolytic deposition method.

FIG. 20 illustrates results of Sb³⁺ concentration-dependent reduction potentials measured using cyclic voltammetry.

FIG. 21 illustrates applied voltage-dependent XRD patterns of a SbₓTe_{y} thin film deposited by varying an applied voltage during wet electrolytic deposition.

FIG. 22 illustrates a FE-SEM image of a SbₓTe_{y} thin film deposited by applying a voltage of −150 mV for one hour on a wafer in a wet electrolytic deposition method.

FIG. 23 illustrates a FE-SEM image of a SbₓTe_{y} thin film deposited by applying a voltage of −175 mV for one hour on a wafer in a wet electrolytic deposition method.

FIG. 24 illustrates a FE-SEM image of a SbₓTe_{y} thin film deposited by applying a voltage of −200 mV for one hour on a wafer in a wet electrolytic deposition method.

FIG. 25 illustrates hydrogen concentration-dependent electromotive force changes in a device when hydrogen is sensed using single-type and n-p junction-type thermochemical gas sensors.

FIG. 26 illustrates time-dependent electromotive force changes under a condition that 3 vol % hydrogen flows so as to measure the reliability of single-type and n-p junction-type thermochemical gas sensors.

FIG. 27 illustrates changes in an electromotive force when 3 vol % hydrogen and dry air are alternately, repeatedly flowed 10 times so as to measure the repeatability of single-type and n-p junction-type thermochemical gas sensors.

### BEST MODE FOR CARRYING OUT THE INVENTION

A thermochemical gas sensor according to a preferred embodiment of the present invention includes a substrate provided with an insulating layer; a seed layer provided on the insulating layer; a thermoelectric thin film provided on the seed layer; an electrode provided on the thermoelectric thin film; a catalyst layer provided on the electrode and causing an exothermic reaction when in contact with gas to be sensed; and an electrode wire electrically connected to the electrode, wherein the thermoelectric thin film is formed of a material including a chalcogenide, wherein the chalcogenide includes one or more chalcogens selected from the group consisting of selenium (Se) and tellurium (Te).

A thermochemical gas sensor according to another preferred embodiment of the present invention includes a substrate provided with an insulating layer; seed layers provided on the insulating layer; a P-type thermoelectric thin film provided on the seed layers; an N-type thermoelectric thin film provided on the seed layers and spaced from the P-type thermoelectric thin film; electrodes provided on the P-type thermoelectric thin film and the N-type thermoelectric thin film; a catalyst layer provided on the electrodes and causing an exothermic reaction when in contact with gas to be sensed; and electrode wires electrically connected to the electrodes, wherein the P-type thermoelectric thin film and the N-type thermoelectric thin film are formed of a material including a chalcogenide, wherein the chalcogenide includes one or more chalcogens selected from the group consisting of selenium (Se) and tellurium (Te), and the P-type thermoelectric thin film is formed of a chalcogenide different from a chalcogenide forming the N-type thermoelectric thin film.

A method of manufacturing a thermochemical gas sensor according to a preferred embodiment of the present invention includes a step of preparing a substrate provided with an insulating layer; a step of forming a seed layer on the insulating layer; a step of forming a thermoelectric thin film on the seed layer using a wet electrolytic deposition method; a step of forming an electrode on the thermoelectric thin film; a step of forming an electrode wire electrically connected to the electrode; and a step of forming a catalyst layer, which causes an exothermic reaction when in contact with gas to be sensed, on the electrode, wherein the thermoelectric thin film is formed of a material including a chalcogenide, wherein the chalcogenide includes one or more chalcogens selected from the group consisting of selenium (Se) and tellurium (Te).

A method of manufacturing a thermochemical gas sensor according to another preferred embodiment of the present invention includes a step of preparing a substrate provided with an insulating layer; a step of forming seed layers on the insulating layer; a step of forming a P-type thermoelectric thin film and an N-type thermoelectric thin film to be spaced from each other on the seed layers using a wet electrolytic deposition method; a step of forming electrodes on the P-type thermoelectric thin film and the N-type thermoelectric thin film; a step of forming electrode wires electrically connected to the electrodes; and a step of forming a catalyst layer, which causes an exothermic reaction when in contact with gas to be sensed, on the electrodes, wherein the thermoelectric thin film is formed of a material including a chalcogenide, wherein the chalcogenide includes one or more chalcogens selected from the group consisting of selenium (Se) and tellurium (Te), and the P-type thermoelectric thin film is formed of a chalcogenide different from a chalcogenide forming the N-type thermoelectric thin film.

### MODE FOR CARRYING OUT THE INVENTION

Hereinafter, the present invention will be described in detail by explaining preferred embodiments of the invention with reference to the attached drawings. However, it should be understood by those skilled in the art that the embodiments are provided for illustrative purposes only, the embodiments can be modified into various forms, and the scope of the present invention is not limited to the embodiments.

Pores of a porous body are classified into three types depending upon the diameter thereof according to the International Union of Pure and Applied Chemistry (IUPAC) definition. Pores having a pore diameter of 2 nm or less are defined as micropores, pores having a pore diameter of 2 to 50 nm are defined as mesopores, and pores having a pore diameter of 50 nm or more are defined as macropores. Hereinafter, macropores refer to pores having a pore diameter of 50 nm or more according to IUPAC, and mesopores refer to pores having a pore diameter of 2 to 50 nm according to IUPAC.

A thermoelectric material-based hydrogen sensor uses the principle that an electromotive force is generated due to temperature changes. In particular, when hydrogen reacts with oxygen by a catalyst such as platinum, oxidization and an exothermic reaction occur, whereby heat is generated due to the catalyst while water is generated as a by-product. When the generated heat is transferred to a thermoelectric thin film, the electromotive force is generated.

A thermochemical gas sensor according to a preferred embodiment of the present invention includes a substrate provided with an insulating layer; a seed layer provided on the insulating layer; a thermoelectric thin film provided on the seed layer; an electrode provided on the thermoelectric thin film; a catalyst layer provided on the electrode and causing an exothermic reaction when in contact with gas to be sensed; and an electrode wire electrically connected to the electrode, wherein the thermoelectric thin film is formed of a material including a chalcogenide, wherein the chalcogenide includes one or more chalcogens selected from the group consisting of selenium (Se) and tellurium (Te).

A thermal grease layer for transferring heat may be provided between the electrode and the catalyst layer.

The thermal grease layer may include one or more thermally conductive materials selected from the group consisting of boron nitride (BN), graphene, carbon nanotubes, active carbon, and carbon black.

The substrate may include a silicon (Si) substrate.

The insulating layer may include a SiO₂ oxide film.

The seed layer preferably has a thickness of 10 to 1000 nm and may be formed of a material including one or more metal types selected from the group consisting of gold (Au), silver (Ag), and copper (Cu).

The catalyst layer may be formed of a composite of one or more materials selected from the group consisting of γ-alumina, graphene, carbon nanotubes, active carbon, and carbon black and a material including one or more metal types selected from the group consisting of platinum (Pt) and palladium (Pd).

The catalyst layer preferably has a thickness of 0.5 to 100 μm.

The chalcogenide may include one or more materials selected from the group consisting of BiₓSe_{y} (1.5≤x≤2.5, SbₓSe_{y} (Bi₁₋ₘSbₘ)ₓSe_{y} (0<m<1, 1.5≤x≤2.5, 2.4≤y≤3.6), PbSe, CdSe, ZnSe, PbTeSe, BiₓTe_{y} (1.5≤x≤2.5, 2.4≤y≤3.6), SbₓTe_{y} (Bi₁₋ₘSbₘ)ₓTe_{y} (0<m<1, 1.5≤x≤2.5, 2.4≤y≤3.6), PbTe, CdTe, ZnTe, La₃Te₄, AgSbTe₂, Ag₂Te, AgPb₁₈BiTe₂₀, (GeTe)ₓ(AgSbTe₂)₁₋ₓ, (x is a real number less than 1), AgₓPb₁₈SbTe₂₀ (x is a real number less than 1), AgₓPb_{22.5}SbTe₂₀ (x is a real number less than 1), SbₓTe₂₀ (x is a real number less than 1), and BiₓSb₂₋ₓTe₃ (x is a real number less than 2).

A thermochemical gas sensor according to another preferred embodiment of the present invention includes a substrate provided with an insulating layer; seed layers provided on the insulating layer; a P-type thermoelectric thin film provided on the seed layers; an N-type thermoelectric thin film provided on the seed layers and spaced from the P-type thermoelectric thin film; electrodes provided on the P-type thermoelectric thin film and the N-type thermoelectric thin film; a catalyst layer provided on the electrodes and causing an exothermic reaction when in contact with gas to be sensed; and electrode wires electrically connected to the electrodes, wherein the P-type thermoelectric thin film and the N-type thermoelectric thin film are formed of a material including a chalcogenide, wherein the chalcogenide includes one or more chalcogens selected from the group consisting of selenium (Se) and tellurium (Te), and the P-type thermoelectric thin film is formed of a chalcogenide different from a chalcogenide forming the N-type thermoelectric thin film.

A thermal grease layer for transferring heat may be provided between the electrodes and the catalyst layer.

The thermal grease layer may include one or more thermally conductive materials selected from the group consisting of boron nitride (BN), graphene, carbon nanotubes, active carbon, and carbon black.

The substrate may include a silicon (Si) substrate.

The insulating layer may include a SiO₂ oxide film.

The seed layers preferably has a thickness of 10 to 1000 nm and may be formed of a material including one or more metal types selected from the group consisting of gold (Au), silver (Ag), and copper (Cu).

The catalyst layer may be formed of a composite of one or more materials selected from the group consisting of γ-alumina, graphene, carbon nanotubes, active carbon, and carbon black and a material including one or more metal types selected from the group consisting of platinum (Pt) and palladium (Pd).

The catalyst layer preferably has a thickness of 0.5 to 100 μm.

The chalcogenide may include one or more materials selected from the group consisting of BiₓSe_{y} (1.5x≤2.5, 2.4≤y≤3.6), SbₓSe_{y} (1.5≤x≤2.5, 2.4≤y≤3.6), (Bi₁₋ₘSbₘ)ₓSe_{y} (0<m<1, 1.5≤x≤2.5, 2.4≤y≤3.6), PbSe, CdSe, ZnSe, PbTeSe, BiₓTe_{y} (1.5≤x≤2.5, 2.4≤y≤3.6), SbₓTe_{y} (1.5≤x≤2.5, 2.4≤y≤3.6), (Bi₁₋ₓSbₘ)ₓTe_{y} (0<m<1, 1.5≤x≤2.5, 2.4≤y≤3.6), PbTe, CdTe, ZnTe, La₃Te₄, AgSbTe₂, Ag₂Te, AgPb₁₈BiTe₂₀, (GeTe)ₓ(AgSbTe₂)₁₋ₓ (x is a real number less than 1), AgₓPb₁₈SbTe₂₀ (x is a real number less than 1), AgₓPb_{22.5}SbTe₂₀ (x is a real number less than 1), SbₓTe₂₀ (x is a real number less than 1), and BiₓSb₂₋ₓTe₃ (x is a real number less than 2).

A method of manufacturing a thermochemical gas sensor according to a preferred embodiment of the present invention includes a step of preparing a substrate provided with an insulating layer; a step of forming a seed layer on the insulating layer; a step of forming a thermoelectric thin film on the seed layer using a wet electrolytic deposition method; a step of forming an electrode on the thermoelectric thin film; a step of forming an electrode wire electrically connected to the electrode; and a step of forming a catalyst layer, which causes an exothermic reaction when in contact with gas to be sensed, on the electrode, wherein the thermoelectric thin film is formed of a material including a chalcogenide, wherein the chalcogenide includes one or more chalcogens selected from the group consisting of selenium (Se) and tellurium (Te).

The method may further include a step of forming a thermal grease layer for transferring heat on the electrode before the step of forming the catalyst layer.

The thermal grease layer may include one or more thermally conductive materials selected from the group consisting of boron nitride (BN), graphene, carbon nanotubes, active carbon, and carbon black.

The substrate may include a silicon (Si) substrate.

The insulating layer may include a SiO₂ oxide film.

The seed layer has a thickness of 10 to 1000 nm and may be formed of a material including one or more metal types selected from the group consisting of gold (Au), silver (Ag), and copper (Cu).

The catalyst layer may be formed of a composite of one or more materials selected from the group consisting of γ-alumina, graphene, carbon nanotubes, active carbon, and carbon black and a material including one or more metal types selected from the group consisting of platinum (Pt) and palladium (Pd).

The catalyst layer preferably has a thickness of 0.5 to 100 μm.

The chalcogenide may include one or more materials selected from the group consisting of BiₓSe_{y} (1.5≤x≤2.5, 2.4≤y≤3.6), SbₓSe_{y} (1.5≤x≤2.5, 2.4≤y≤3.6), (Bi₁₋ₘSbₘ)ₓSe_{y} (0<m<1, 1.5≤x≤2.5, 2.4≤y≤3.6), PbSe, CdSe, ZnSe, PbTeSe, BiₓTe_{y} (1.5≤x≤2.5, 2.4≤y≤3.6), SbₓTe_{y} (Bi₁₋ₘSbₘ)ₓTe_{y} (0<m<1, 1.5≤x≤2.5, 2.4≤y≤3.6), PbTe, CdTe, ZnTe, La₃Te₄, AgSbTe₂, Ag₂Te, AgPb₁₈BiTe₂₀, (GeTe)ₓ(AgSbTe₂)₁₋ₓ (x is a real number less than 1), AgₓPb₁₈SbTe₂₀ (x is a real number less than 1), AgₓPb_{22.5}SbTe₂₀ (x is a real number less than 1), SbₓTe₂₀ (x is a real number less than 1), and BiₓSb₂₋ₓTe₃ (x is a real number less than 2).

A method of manufacturing a thermochemical gas sensor according to another preferred embodiment of the present invention includes a step of preparing a substrate provided with an insulating layer; a step of forming seed layers on the insulating layer; a step of forming a P-type thermoelectric thin film and an N-type thermoelectric thin film to be spaced from each other on the seed layers using a wet electrolytic deposition method; a step of forming electrodes on the P-type thermoelectric thin film and the N-type thermoelectric thin film; a step of forming electrode wires electrically connected to the electrodes; and a step of forming a catalyst layer, which causes an exothermic reaction when in contact with gas to be sensed, on the electrodes, wherein the thermoelectric thin film is formed of a material including a chalcogenide, wherein the chalcogenide includes one or more chalcogens selected from the group consisting of selenium (Se) and tellurium (Te), and the P-type thermoelectric thin film is formed of a chalcogenide different from a chalcogenide forming the N-type thermoelectric thin film.

The method may further include a step of forming a thermal grease layer for transferring heat on the electrodes before the step of forming the catalyst layer.

The thermal grease layer may include one or more thermally conductive materials selected from the group consisting of boron nitride (BN), graphene, carbon nanotubes, active carbon, and carbon black.

The substrate may include a silicon (Si) substrate.

The insulating layer may include a SiO₂ oxide film.

The seed layers preferably has a thickness of 10 to 1000 nm and may be formed of a material including one or more metal types selected from the group consisting of gold (Au), silver (Ag), and copper (Cu).

The catalyst layer may be formed of a composite of one or more materials selected from the group consisting of γ-alumina, graphene, carbon nanotubes, active carbon, and carbon black and a material including one or more metal types selected from the group consisting of platinum (Pt) and palladium (Pd).

The catalyst layer preferably has a thickness of 0.5 to 100 μm.

The chalcogenide may include one or more materials selected from the group consisting of BiₓSe_{y} (1.5≤x≤2.5, SbₓSe_{y} (Bi₁₋ₘSbₘ)ₓSe_{y} (0<m<1, 1.5≤x≤2.5, 2.4≤y≤3.6), PbSe, CdSe, ZnSe, PbTeSe, BiₓTe_{y} (1.5≤x≤2.5, 2.4≤y≤3.6), SbₓTe_{y} (Bi₁₋ₘSbₘ)ₓTe_{y} (0<m<1, 1.5≤x≤2.5, 2.4≤y≤3.6), PbTe, CdTe, ZnTe, La₃Te₄, AgSbTe₂, Ag₂Te, AgPb₁₈BiTe₂₀, (GeTe)ₓ(AgSbTe₂)₁₋ₓ (x is a real number less than 1), AgₓPb₁₈SbTe₂₀ (x is a real number less than 1), AgₓPb_{22.5}SbTe₂₀ (x is a real number less than 1), SbₓTe₂₀ (x is a real number less than 1), and BiₓSb₂₋ₓTe₃ (x is a real number less than 2).

Hereinafter, a thermochemical gas sensor according to a preferred embodiment of the present invention is described in more detail.

### EXAMPLE 1

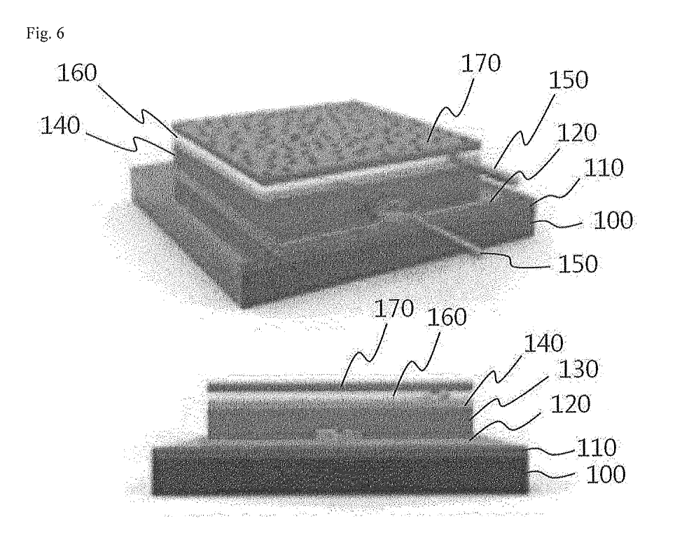

FIG. 6 illustrates a structure of the thermochemical gas sensor according to Example 1 of the present invention.

Referring to FIG. 6, the thermochemical gas sensor according to Example 1 of the present invention includes a substrate 100 provided with an insulating layer 110, a seed layer 120 provided on the insulating layer 110, a thermoelectric thin film 130 provided on the seed layer 120, an electrode 140 provided on the thermoelectric thin film 130, a catalyst layer 170 provided on the electrode 140 and causing an exothermic reaction when in contact with gas to be sensed, and an electrode wire 150 electrically connected to the electrode 140.

The thermoelectric thin film 130 is composed of a material including a chalcogenide, and the chalcogenide includes one or more chalcogens selected from the group consisting of selenium (Se) and tellurium (Te). The chalcogenide, which is a binary or higher compound including one or more chalcogens selected from the group consisting of selenium (Se) and tellurium (Te), may include one or more materials selected from the group consisting of BiₓSe_{y} (1.5≤x≤2.5, 2.4≤y≤3.6), SbₓSe_{y} (1.5≤x≤2.5, 2.4≤y≤3.6), (Bi₁₋ₘSbₘ)ₓSe_{y} (0<m<1, 1.5≤x≤2.5, 2.4≤y≤3.6), PbSe, CdSe, ZnSe, PbTeSe, BiₓTe_{y} (1.5≤x≤2.5, 2.4≤y≤3.6), SbₓTe_{y} (1.5≤x≤2.5, 2.4≤y≤3.6), (Bi₁₋ₘSbₘ)ₓTe_{y} (0<m<1, 1.5≤x≤2.5, 2.4≤y≤3.6), PbTe, CdTe, ZnTe, La₃Te₄, AgSbTe₂, Ag₂Te, AgPb₁₈BiTe₂₀, (GeTe)ₓ(AgSbTe₂)₁₋ₓ (x is a real number less than 1), AgₓPb₁₈SbTe₂₀ (x is a real number less than 1), AgₓPb_{22.5}SbTe₂₀ (x is a real number less than 1), SbₓTe₂₀ (x is a real number less than 1), and BiₓSb₂₋ₓTe₃ (x is a real number less than 2). In particular, Bi₂Te₃ and Sb₂Te₃ exhibit high thermoelectric properties at room temperature, and thermochemical gas sensors based on these materials may be operated at room temperature. The thermoelectric thin film 130 preferably has a thickness of 0.5 to 50 μm.

A thermal grease layer 160 for transferring heat may be provided between the electrode 140 and the catalyst layer 170. The thermal grease layer 160 serves to uniformly transfer heat generated due to a catalyst to the entire sensor. The thermal grease layer 160 may include a thermally conductive material such as boron nitride (BN), graphene, carbon nanotubes, active carbon, carbon black, or a mixture thereof.

The substrate 100 may include a silicon (Si) substrate.

The insulating layer 110 may include a SiO₂ oxide film.

The seed layer 120 preferably has a thickness of 10 to 1000 nm and may be composed of a material including one or more metal types selected from the group consisting of gold (Au), silver (Ag), and copper (Cu).

The catalyst layer 170 may be composed of a material including one or more metal types selected from the group consisting of platinum (Pt) and palladium (Pd), or a composite of one or more materials selected from the group consisting of γ-alumina, graphene, carbon nanotubes, active carbon, and carbon black and a material including one or more metal types selected from the group consisting of platinum (Pt) and palladium (Pd). The catalyst layer 170 preferably has a thickness of 0.5 to 100 μm.

### EXAMPLE 2

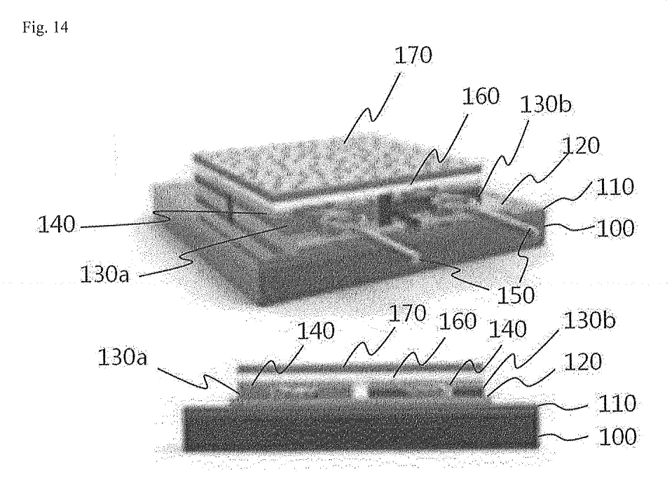

FIG. 14 illustrates a structure of the thermochemical gas sensor according to Example 2 of the present invention.

Referring to FIG. 14, the thermochemical gas sensor according to Example 2 of the present invention includes a substrate 100 provided with an insulating layer 110, seed layers 120 provided on the insulating layer 110, a P-type thermoelectric thin film 130a provided on the seed layers 120, an N-type thermoelectric thin film 130b provided on the seed layers 120 and spaced from the P-type thermoelectric thin film 130a, electrodes 140 provided on the P-type and N-type thermoelectric thin films 130a and 130b, a catalyst layer 170 provided on the electrodes 140 and causing an exothermic reaction when in contact with gas to be sensed, and electrode wires 150 electrically connected to the electrodes 140.

The P-type and N-type thermoelectric thin films 130a and 130b are composed of a material including a chalcogenide, and the chalcogenide includes one or more chalcogens selected from the group consisting of selenium (Se) and tellurium (Te). The P-type thermoelectric thin film is composed of a chalcogenide different from a chalcogenide composing the N-type thermoelectric thin film. The chalcogenide, which is a binary or higher compound including one or more chalcogens selected from the group consisting of selenium (Se) and tellurium (Te), may include one or more materials selected from the group consisting of BiₓSe_{y} (1.5≤x≤2.5, 2.4≤y≤3.6), SbₓSe_{y} (1.5≤x≤2.5, 2.4≤y≤3.6), (Bi₁₋ₘSbₘ)ₓSe_{y} (0<m<1, 1.5≤x≤2.5, 2.4≤y≤3.6), PbSe, CdSe, ZnSe, PbTeSe, BiₓTe_{y} (1.5≤x≤2.5, 2.4≤y≤3.6), SbₓTe_{y} (1.5≤x≤2.5, 2.4≤y≤3.6), (Bi₁₋ₘSbₘ)ₓTe_{y} (0<m<1, 1.5≤x≤2.5, 2.4≤y≤3.6), PbTe, CdTe, ZnTe, La₃Te₄, AgSbTe₂, Ag₂Te, AgPb₁₈BiTe₂₀, (GeTe)ₓ(AgSbTe₂)₁₋ₓ (x is a real number less than 1), AgₓPb₁₈SbTe₂₀ (x is a real number less than 1), AgₓPb_{22.5}SbTe₂₀ (x is a real number less than 1), SbₓTe₂₀ (x is a real number less than 1), and BiₓSb₂₋ₓTe₃ (x is a real number less than 2). In particular, Bi₂Te₃ and Sb₂Te₃ exhibit high thermoelectric properties at room temperature, and thermochemical gas sensors based on these materials may be operated at room temperature. The P-type and N-type thermoelectric thin films 130a and 130b preferably have a thickness of 0.5 to 50 μm.

A thermal grease layer 160 for transferring heat may be provided between the electrodes 140 and the catalyst layer 170. The thermal grease layer 160 serves to uniformly transfer heat generated due to a catalyst to the entire sensor. The thermal grease layer 160 may include a thermally conductive material such as boron nitride (BN), graphene, carbon nanotubes, active carbon, carbon black, or a mixture thereof.

The substrate 100 may include a silicon (Si) substrate.

The insulating layer 110 may include a SiO₂ oxide film.

The seed layers 120 preferably has a thickness of 10 to 1000 nm and may be composed of a material including one or more metal types selected from the group consisting of gold (Au), silver (Ag), and copper (Cu).

The catalyst layer 170 may be composed of a material including one or more metal types selected from the group consisting of platinum (Pt) and palladium (Pd), or a composite of one or more materials selected from the group consisting of γ-alumina, graphene, carbon nanotubes, active carbon, and carbon black and a material including one or more metal types selected from the group consisting of platinum (Pt) and palladium (Pd). The catalyst layer 170 preferably has a thickness of 0.5 to 100 μm.

Hereinafter, a method of manufacturing a thermochemical gas sensor according to a preferred embodiment of the present invention is described in more detail.

### EXAMPLE 1

A substrate, on which an insulating layer was formed, was used as a matrix of a device, and a seed layer was formed on the insulating layer. Subsequently, a thermoelectric material was plated on the seed layer using a wet electrolytic deposition method to form a thermoelectric thin film. Subsequently, an electrode was formed on the thermoelectric thin film, and a catalyst layer was formed on the electrode. As a result, a novel thermoelectric thin film-based thermochemical gas sensor was manufactured.

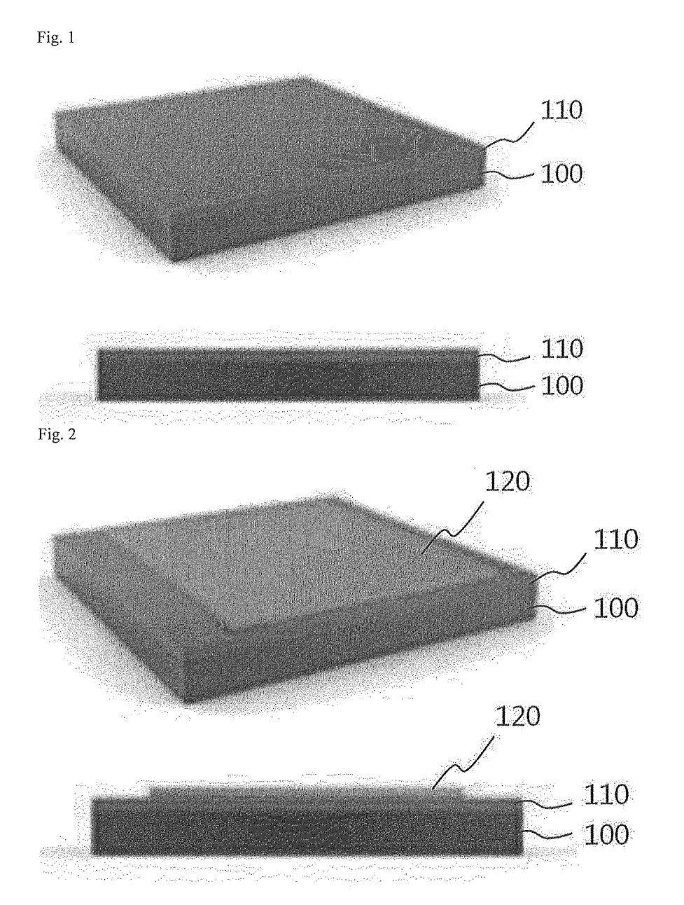

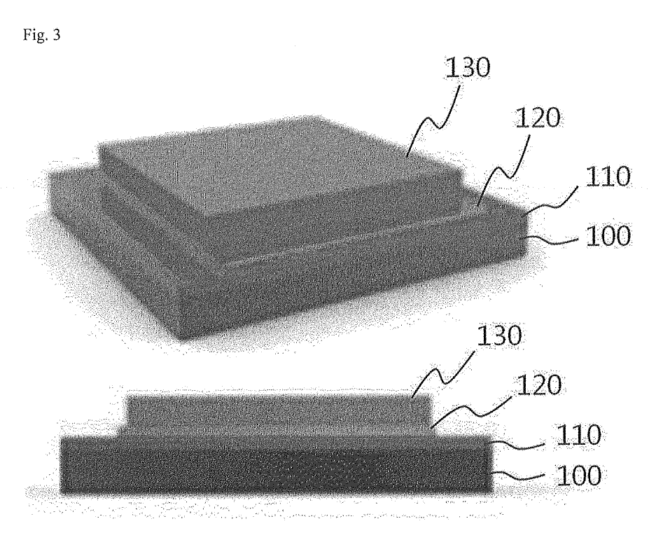

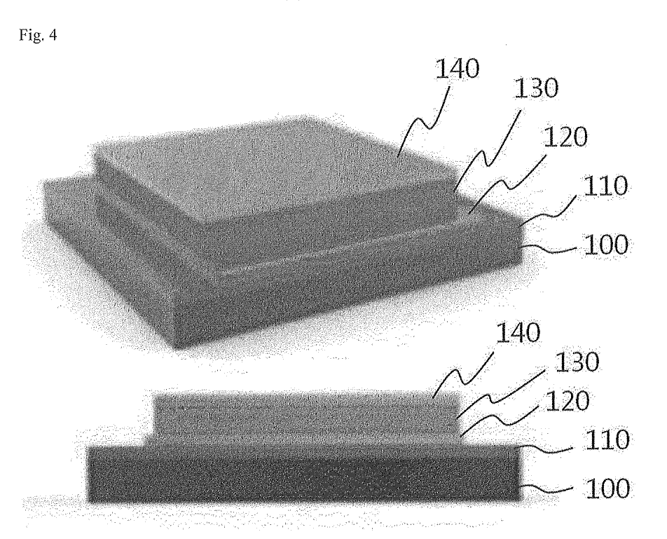

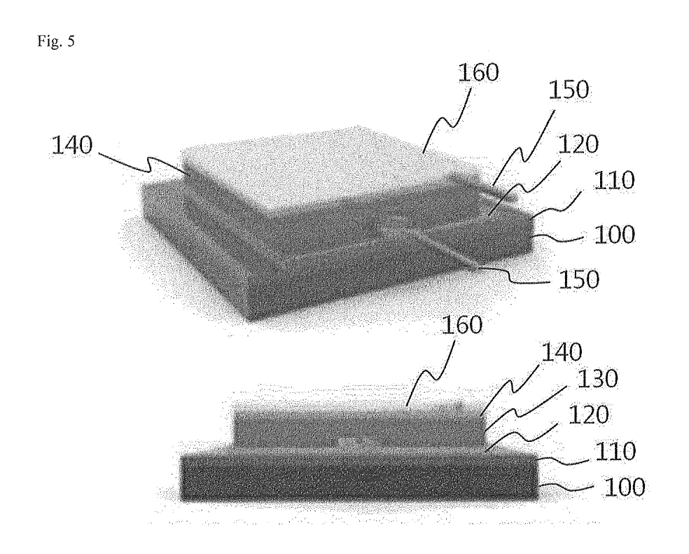

FIGS. 1 to 6 illustrate a method of manufacturing a thermochemical gas sensor according to Example 1.

Referring to FIGS. 1 to 6, a substrate 100 provided with an insulating layer 110 was prepared to manufacture the thermochemical gas sensor. The substrate 100 may include a silicon (Si) substrate. The insulating layer 110 may include a SiO₂ oxide film.

A seed layer 120 was formed on the insulating layer 110. The seed layer 120 preferably has a thickness of 10 to 1000 nm, and may be formed of a material including one or more metal types selected from the group consisting of gold (Au), silver (Ag), and copper (Cu). The seed layer 120 may be formed by deposition using various methods. For example, the seed layer 120 may be formed using sputtering, an electron beam (E-beam), etc.

A thermoelectric thin film 130 was formed on the seed layer 120 using a wet electrolytic deposition method.

In the present invention, a wet electrolytic deposition method capable of easily synthesizing a thermoelectric thin film at low cost is used. By using a wet electrolytic deposition method, a thermoelectric thin film 130 having a desired type and composition may be easily synthesized to a uniform thickness at less process costs. In addition, the wet electrolytic deposition method is advantageous in that a thermoelectric thin film 130 may be synthesized to a desired several micron thickness, which allows miniaturization of a sensor. In addition, a thermochemical gas sensor based on the thermoelectric thin film 130 is advantageous in that gas in a broad concentration range may be sensed and physical/chemical changes, such as phase change, of the thermoelectric thin film 130 are not involved even if repeatedly exposed to gas. Further, a thermoelectric thin film 130 having a desired thickness and composition may be synthesized by controlling wet electrolytic deposition conditions such as an electrolyte and voltage.

In the wet electrolytic deposition, a precursor including one or more chalcogens selected from the group consisting of selenium (Se) and tellurium (Te), a precursor binding with the chalcogen to form a chalcogenide, and an electrolyte including an acid may be used. The acid, which is a substance capable of dissolving the precursor including a chalcogen and the precursor binding with a chalcogen to form a chalcogenide, may be an acidic solution such as nitric acid (HNO₃) and hydrofluoric acid (HF). For example, the wet electrolytic deposition may be performed by applying voltage to a two-electrode or three-electrode system using a rectifier.

The thermoelectric thin film 130 is formed of a material including a chalcogenide, and the chalcogenide includes one or more chalcogens selected from the group consisting of selenium (Se) and tellurium (Te). The chalcogenide may be a binary or higher compound including one or more chalcogens selected from the group consisting of selenium (Se) and tellurium (Te) and may include one or more materials selected from the group consisting of BiₓSe_{y} (1.5≤x≤2.5, 2.4≤y≤3.6), SbₓSe_{y} (1.5≤x≤2.5, 2.4≤y≤3.6), (Bi₁₋ₘSbₘ)ₓSe_{y} (0<m<1, 1.5≤x≤2.5, 2.4≤y≤3.6), PbSe, CdSe, ZnSe, PbTeSe, BiₓTe_{y} (1.5≤x≤2.5, 2.4≤y≤3.6), SbₓTe_{y} (1.5≤x≤2.5, 2.4≤y≤3.6), (Bi₁₋ₘSbₘ)ₓTe_{y} (0<m<1, 1.5≤x≤2.5, 2.4≤y≤3.6), PbTe, CdTe, ZnTe, La₃Te₄, AgSbTe₂, Ag₂Te, AgPb₁₈BiTe₂₀, (GeTe)ₓ(AgSbTe₂)₁₋ₓ (x is a real number less than 1), AgₓPb₁₈SbTe₂₀ (x is a real number less than 1), AgₓPb_{22.5}SbTe₂₀ (x is a real number less than 1), SbₓTe₂₀ (x is a real number less than 1), and BiₓSb₂₋ₓTe₃ (x is a real number less than 2). In particular, Bi₂Te₃ and Sb₂Te₃ exhibit high thermoelectric properties at room temperature, and thermochemical gas sensors based on these materials may be operated at room temperature.

Hereinafter, a precursor (source) for forming the chalcogenide is described in more detail.

For example, to form BiₓTe_{y} (1.5≤x≤2.5, 2.4≤y≤3.6), tellurium dioxide (TeO₂), which is a precursor of tellurium, a bismuth-based salt or bismuth-based alkoxide, such as Bi(NO₃)₃.5H₂O, which is a precursor of bismuth (Bi), and the like may be used.

For example, to form BiₓSe_{y} (1.5≤x≤2.5, 2.4≤y≤3.6), selenium dioxide (SeO₂), which is a precursor of selenium, a bismuth-based salt or bismuth-based alkoxide, such as Bi(NO₃)₃.5H₂O, which is a precursor of bismuth (Bi), and the like may be used.

For example, to form SbₓTe_{y} (1.5≤x≤2.5, 2.4≤y≤3.6), tellurium dioxide (TeO₂), which is a precursor of tellurium, an antimony-based salt or antimony-based alkoxide, such as Sb₂O₃, which is a precursor of antimony (Sb), and the like may be used.

For example, to form CdTe, tellurium dioxide (TeO₂), which is a precursor of tellurium, a cadmium-based salt or cadmium-based alkoxide, which is a precursor of cadmium (Cd), and the like may be used.

For example, to form ZnTe, tellurium dioxide (TeO₂), which is a precursor of tellurium, a zinc-based salt or zinc-based alkoxide, which is a precursor of zinc (Zn), and the like may be used.

For example, to form PbTe, tellurium dioxide (TeO₂), which is a precursor of tellurium, a lead-based salt or lead-based alkoxide, which is a precursor of lead (Pb), and the like may be used.

For example, to form Ag₂Te, tellurium dioxide (TeO₂), which is a precursor of tellurium, a silver-based salt or silver-based alkoxide, which is a precursor of silver (Ag), and the like may be used.

The thermoelectric thin film 130 is preferably formed to a thickness of 0.5 to 50 μm.

The electrode 140 is formed on the thermoelectric thin film 130. The electrode 140 is preferably formed by electroplating one or more metal types selected from the group consisting of gold (Au), silver (Ag), and copper (Cu). Here, the electroplating may be accomplished by applying current to a two-electrode system by means of a rectifier while stirring with a magnetic bar.

The electrode wires 150 are formed to be electrically connected to the electrode 140. The electrode wires 150 may also be electrically connected to the seed layer 120 so as to evaluate the characteristics of a thermochemical gas sensor. The electrode wires 150 may be formed of a conductive copper wire, for example, using silver paste.

The catalyst layer 170, which causes an exothermic reaction when in contact with gas to be sensed, is formed on the electrode 140. The catalyst layer 170 is preferably formed with a thickness of 0.5 to 100 μm. The catalyst layer 170 is formed of a material including one or more metal types selected from the group consisting of platinum (Pt) and palladium (Pd). In addition, the catalyst layer 170 may be formed of a composite of one or more materials selected from the group consisting of γ-alumina, graphene, carbon nanotubes, active carbon, and carbon black and a material including one or more metal types selected from the group consisting of platinum (Pt) and palladium (Pd). For example, the composite may be a porous platinum-alumina composite including 0.1 to 12% by volume of platinum (Pt) and 88 to 99.9% by volume of alumina in consideration of an exothermic reaction with gas to be sensed. As another example, the composite may be a porous palladium-alumina composite including 0.1 to 12% by volume of palladium (Pd) and 88 to 99.9% by volume of alumina in consideration of an exothermic reaction with gas to be sensed. The catalyst layer 170 may be formed by applying a paste including a material including one or more metal types selected from the group consisting of platinum (Pt) and palladium (Pd), or a paste including a composite of one or more materials selected from the group consisting of γ-alumina, graphene, carbon nanotubes, active carbon, and carbon black and a material including one or more metal types selected from the group consisting of platinum (Pt), and palladium (Pd) onto the electrode 140.

Hereinafter, methods of manufacturing the porous platinum-alumina composite or the porous palladium-alumina composite are described in detail.

A mixture of styrene and distilled water was prepared, and potassium persulfate was added to the mixture to synthesize a polystyrene solution. Subsequently, the polystyrene solution was dried to produce colloidal crystals. A precursor solution of a platinum-alumina composite or a palladium-alumina composite was synthesized, and the colloidal crystals produced through the drying process were immersed in the precursor solution of a platinum-alumina composite or palladium-alumina composite. Subsequently, the colloidal crystals immersed in the precursor solution of a platinum-alumina composite or a palladium-alumina composite were dried and calcined to remove the colloidal polystyrene crystals.

The platinum-alumina composite precursor solution may be a solution including aluminum isopropoxide (C₉H₂₁O₃Al) and chloroplatinic acid (H₂PtCl₆), and the palladium-alumina composite precursor solution may be a solution including aluminum isopropoxide (C₉H₂₁O₃Al) and chloropalladic acid (H₂PdCl₆).

The porous platinum-alumina composite or the porous palladium-alumina composite prepared in this method is a porous material having a plurality of macropores and mesopores, and causes an exothermic reaction when in contact with gas to be sensed (e.g., hydrogen gas).

Since polystyrene colloidal crystals are used as a mold and the mold is removed in the aforementioned method of preparing a porous platinum-alumina composite or porous palladium-alumina composite, macropores having a regular arrangement may be produced. A platinum-alumina composite or palladium-alumina composite having macro-mesopores, wherein the macropores and intrinsic mesopores of alumina are formed and function together, may be synthesized. A molecular diffusion rate increases when macro-mesopores are formed in the platinum-alumina composite or palladium-alumina composite, whereby a rapid response characteristic and high sensitivity may be provided.

Polystyrene is present in a bead form in the polystyrene solution. The size of the bead is related to a reaction time. Since the size of macropores is related to the size of colloidal crystals, it is also related to the size of bead. Accordingly, the size of macropores may be controlled by adjusting the bead size through adjustment of the reaction time, the amount of potassium persulfate, a ratio of distilled water to styrene, etc.

Before the step of forming the catalyst layer 170, the thermal grease layer 160 for transferring heat may be formed on the electrode 140. The thermal grease layer 160 is formed to uniformly transfer heat, which is generated due to a catalyst, to the entire sensor. The thermal grease layer 160 may include a thermally conductive material such as boron nitride (BN), graphene, carbon nanotubes, active carbon, carbon black, or a mixture thereof. The thermal grease layer 160 may be formed by applying a paste, which includes a thermally conductive material such as boron nitride (BN), graphene, carbon nanotubes, active carbon, carbon black, or a mixture thereof, onto the electrode 140.

By this method, the thermoelectric thin film 130 exhibiting thermoelectric properties in a suitable temperature range may be easily synthesized depending upon an operation temperature. In addition, various desired gas types may be sensed through a change in a catalyst reacting selectively with gas to be sensed. Further, a method of evaluating a thermoelectric performance index with gas can be utilized using a technology of sensing changes in temperature and a minute electromotive force exhibited upon sensing of gas.

### EXAMPLE 2

A substrate, on which an insulating layer was formed, was used as a matrix of a device, and seed layers were formed on the insulating layer. Subsequently, a thermoelectric material was plated on the seed layers using a wet electrolytic deposition method to form P-type and N-type thermoelectric thin films. Subsequently, electrodes were formed on the P-type and N-type thermoelectric thin films to maximize thermoelectric properties of a device through an N-P junction, and a catalyst layer was formed on the electrodes. As a result, a novel thermoelectric thin film-based thermochemical gas sensor was manufactured.

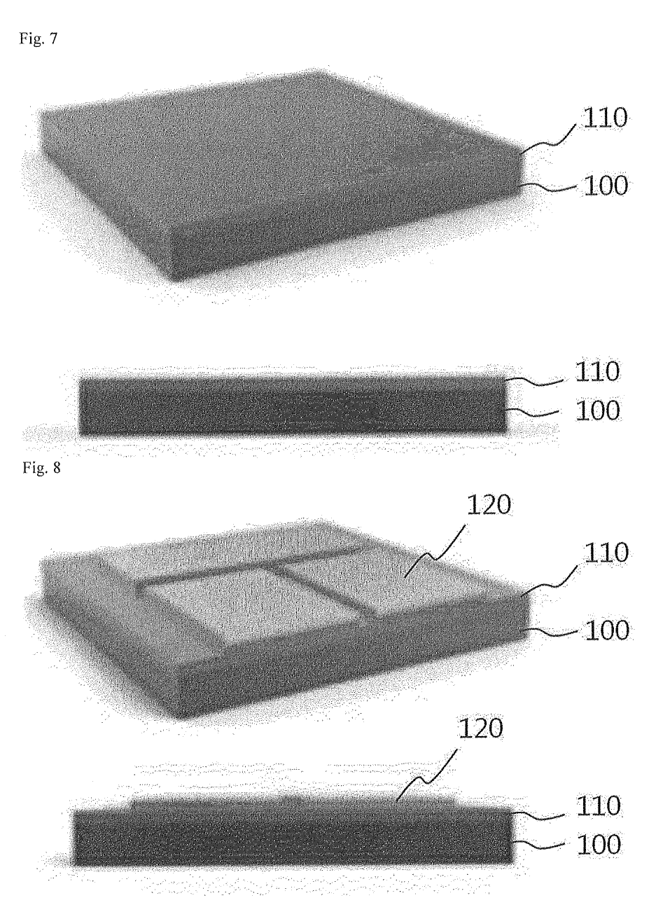

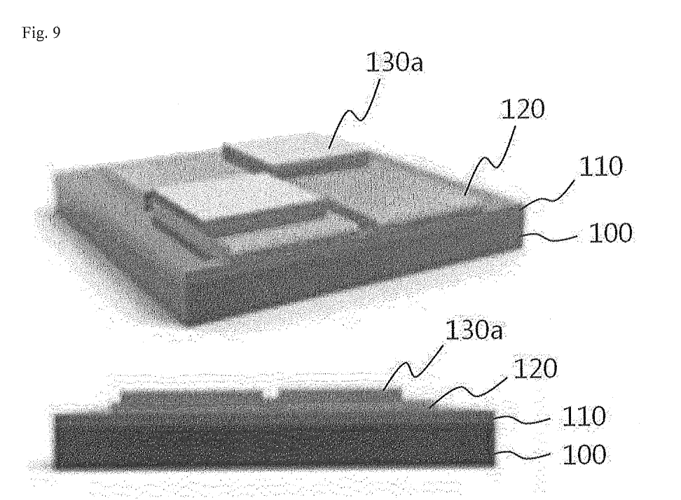

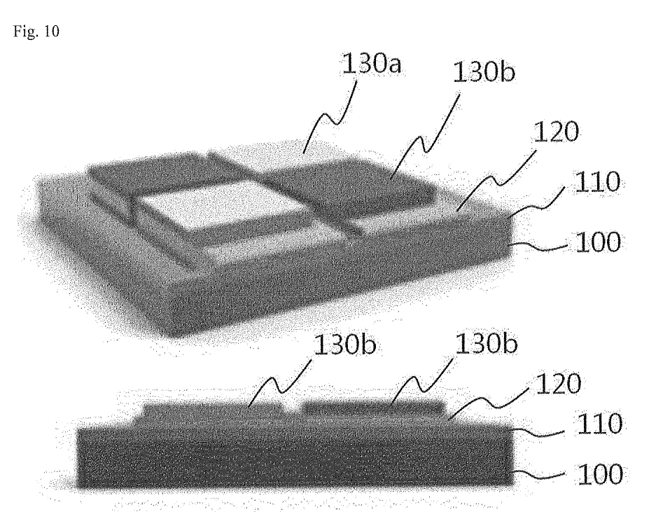

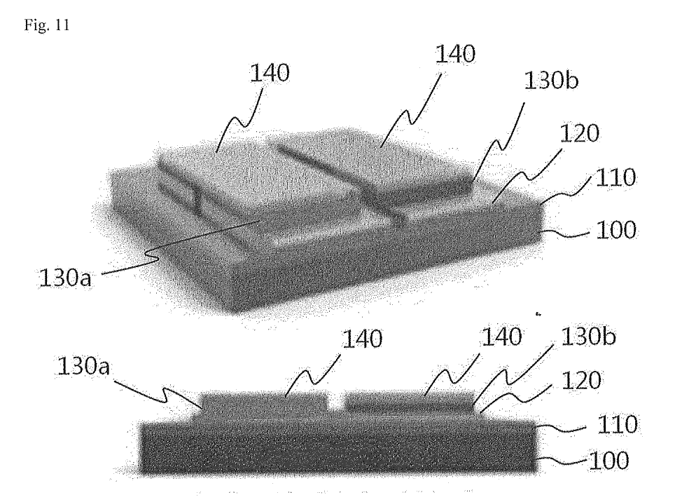

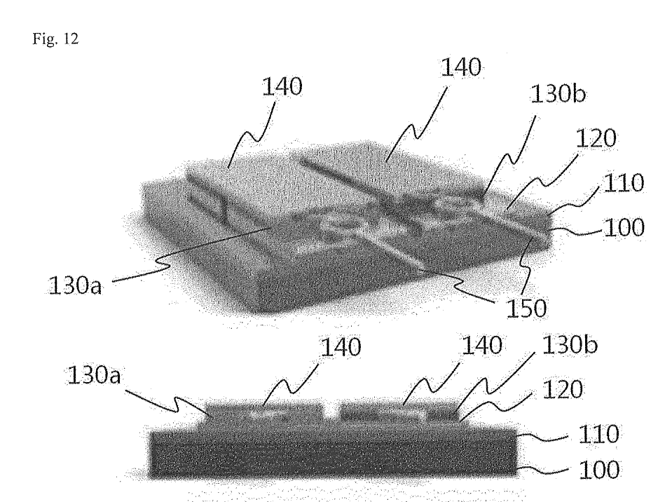

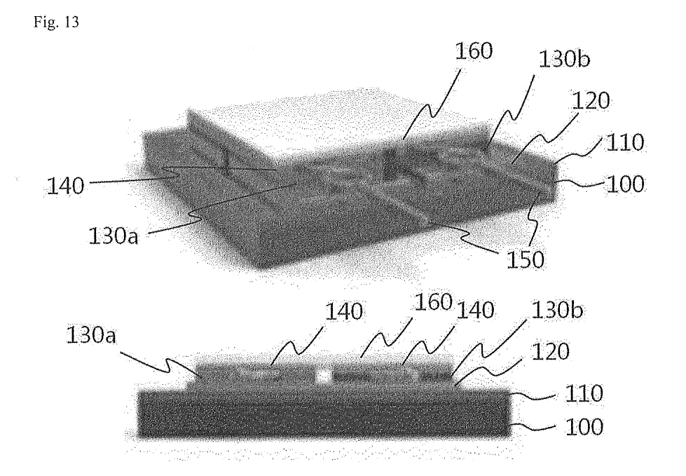

FIGS. 7 to 14 illustrate a method of manufacturing a thermochemical gas sensor according to Example 2.

Referring to FIGS. 7 to 14, a substrate 100 provided with an insulating layer 110 was prepared to manufacture the thermochemical gas sensor. The substrate 100 may include a silicon (Si) substrate. The insulating layer 110 may include a SiO₂ oxide film.

Seed layers 120 was formed on the insulating layer 110. The seed layers 120 preferably has a thickness of 10 to 1000 nm, and may be formed of a material including one or more metal types selected from the group consisting of gold (Au), silver (Ag), and copper (Cu). The seed layers 120 may be formed by deposition using various methods. For example, the seed layers 120 may be formed using sputtering, an electron beam (E-beam), etc.

The P-type thermoelectric thin film 130a and the N-type thermoelectric thin film 130b are formed to be spaced from each other on the seed layers 120 using a wet electrolytic deposition method. A plurality of P-type thermoelectric thin films 130a may be formed to be spaced from each other. In addition, a plurality of N-type thermoelectric thin films 130b may be formed to be spaced from each other.

In the present invention, a wet electrolytic deposition method capable of easily synthesizing the thermoelectric thin films 130a and 130b at low cost is used. By using a wet electrolytic deposition method, thermoelectric thin films 130a and 130b having a desired type and composition may be easily synthesized to a uniform thickness at less process costs. In addition, the wet electrolytic deposition method is advantageous in that thermoelectric thin films 130a and 130b may be synthesized to a desired several micron thickness, which allows miniaturization of a sensor. In addition, a thermochemical gas sensor based on the thermoelectric thin films 130a and 130b is advantageous in that gas in a broad concentration range may be sensed and physical/chemical changes, such as phase change, of the thermoelectric thin films 130a and 130b are not involved even if repeatedly exposed to gas. Further, thermoelectric thin films 130a and 130b having a desired thickness and composition may be synthesized by controlling wet electrolytic deposition conditions such as an electrolyte and voltage.

To form the P-type thermoelectric thin film 130a, a part on which the N-type thermoelectric thin film 130b is to be formed is masked (shielded) using a mask (not shown) and wet electrolytic deposition is performed. In addition, to form the N-type thermoelectric thin film 130b, the part, on which the P-type thermoelectric thin film 130a has been formed, is masked (shielded) using a mask (not shown) and wet electrolytic deposition is performed. On the contrary, the P-type thermoelectric thin film 130a may be formed after forming the N-type thermoelectric thin film 130b. That is, to form the N-type thermoelectric thin film 130b, a part on which the P-type thermoelectric thin film 130a is to be formed may be masked (shielded) using a mask (not shown) and wet electrolytic deposition may be performed. In addition, to form the P-type thermoelectric thin film 130a, a part on which the N-type thermoelectric thin film 130b has been formed may be masked (shielded) using a mask (not shown) and wet electrolytic deposition may be performed.

In the wet electrolytic deposition, a precursor including one or more chalcogens selected from the group consisting of selenium (Se) and tellurium (Te), a precursor binding with the chalcogen to form a chalcogenide, and an electrolyte including an acid may be used. The acid, which is a substance capable of dissolving the precursor including a chalcogen and the precursor binding with a chalcogen to form a chalcogenide, may be an acidic solution such as nitric acid (HNO₃) and hydrofluoric acid (HF). For example, the wet electrolytic deposition may be performed by applying voltage to a two-electrode or three-electrode system using a rectifier.

The P-type and N-type thermoelectric thin films 130a and 130b are formed of a material including a chalcogenide, and the chalcogenide includes one or more chalcogens selected from the group consisting of selenium (Se) and tellurium (Te). The chalcogenide may be a binary or higher compound including one or more chalcogens selected from the group consisting of selenium (Se) and tellurium (Te) and may include one or more materials selected from the group consisting of BiₓSe_{y} (1.5≤x≤2.5, 2.4≤y≤3.6), SbₓSe_{y} (1.5≤x≤2.5, 2.4≤y≤3.6), (Bi₁₋ₘSbₘ)ₓSe_{y} (0<m<1, 1.5≤x≤2.5, 2.4≤y≤3.6), PbSe, CdSe, ZnSe, PbTeSe, BiₓTe_{y} (1.5≤x≤2.5, 2.4≤y≤3.6), SbₓTe_{y} (1.5≤x≤2.5, 2.4≤y≤3.6), (Bi₁₋ₘSbₘ)ₓTe_{y} (0<m<1, 1.5≤x≤2.5, 2.4≤y≤3.6), PbTe, CdTe, ZnTe, La₃Te₄, AgSbTe₂, Ag₂Te, AgPb₁₈BiTe₂₀, (GeTe)ₓ(AgSbTe₂)₁₋ₓ (x is a real number less than 1), AgₓPb₁₈SbTe₂₀ (x is a real number less than 1), AgₓPb_{22.5}SbTe₂₀ (x is a real number less than 1), SbₓTe₂₀ (x is a real number less than 1), and BiₓSb₂₋ₓTe₃ (x is a real number less than 2). In particular, Bi₂Te₃ and Sb₂Te₃ exhibit high thermoelectric properties at room temperature, and thermochemical gas sensors based on these materials may be operated at room temperature. The P-type thermoelectric thin film is formed of a chalcogenide different from that of the N-type thermoelectric thin film. For example, the SbₓTe_{y} (1.5≤x≤2.5, 2.4≤y≤3.6), PbSe, ZnSe, CdTe, and ZnTe may be used as a P-type thermoelectric thin film. NBiₓSe_{y} SbₓSe_{y} (1.5≤x≤2.5, 2.4≤y≤3.6), CdSe, BiₓTe_{y} (1.5≤x≤2.5, 2.4≤y≤3.6), La₃Te₄, and SbₓTe₂₀ (x is a real number less than 1) may be used as an N-type thermoelectric thin film. (Bi₁₋ₘSbₘ)ₓSe_{y} (0<m<1, 1.5≤x≤2.5, 2.4≤y≤3.6), (Bi₁₋ₘSbₘ)ₓTe_{y} (0<m<1, 1.5≤x≤2.5, 2.4≤y≤3.6), PbTe, PbTeSe, AgSbTe₂, Ag₂Te, AgPb₁₈BiTe₂₀, (GeTe)ₓ(AgSbTe₂)₁₋ₓ (x is a real number less than 1), AgₓPb₁₈SbTe₂₀ (x is a real number less than 1), AgₓPb_{22.5}SbTe₂₀ (x is a real number less than 1), and BiₓSb₂₋ₓTe₃ (x is a real number less than 2) may be used as a P-type or N-type thermoelectric thin film depending upon compositions thereof. In consideration of these points, the P-type thermoelectric thin film 130a may be composed of SbₓTe_{y} (1.5≤x≤2.5, 2.4≤y≤3.6), PbSe, ZnSe, CdTe, ZnTe, (Bi₁₋ₘSbₘ)ₓSe_{y} (0<m<1, 1.5≤x≤2.5, 2.4≤y≤3.6), (Bi₁₋ₘSbₘ)ₓTe_{y} (0<m<1, 1.523 x≤2.5, 2.4≤y≤3.6), PbTe, PbTeSe, AgSbTe₂, Ag₂Te, AgPb₁₈BiTe₂₀, (GeTe)ₓ(AgSbTe₂)₁₋ₓ (x is a real number less than 1), AgₓPb₁₈SbTe₂₀ (x is a real number less than 1), AgₓPb_{22.5}SbTe₂₀ (x is a real number less than 1), BiₓSb₂₋ₓTe₃ (x is a real number less than 2), etc., and the N-type thermoelectric thin film 130b may be composed of BiₓSe_{y} (1.523 x≤2.5, 2.4≤y≤3.6), SbₓSe_{y} (1.5≤x≤2.5, 2.4≤y≤3.6), CdSe, BiₓTe_{y} (1.5≤x≤2.5, 2.4≤y≤3.6), La₃Te₄, SbₓTe₂₀ (x is a real number less than 1), (Bi₁₋ₘSbₘ)ₓSe_{y} (0<m<1, 1.5≤x≤2.5, 2.4≤y≤3.6), (Bi₁₋ₘSbₘ)ₓTe_{y} (0<m<1, 1.5≤x≤2.5, 2.4≤y≤3.6), PbTe, PbTeSe, AgSbTe₂, Ag₂Te, AgPb₁₈BiTe₂₀, (GeTe)ₓ(AgSbTe₂)₁₋ₓ (x is a real number less than 1), AgₓPb₁₈SbTe₂₀ (x is a real number less than 1), AgₓPb_{22.5}SbTe₂₀ (x is a real number less than 1), BiₓSb₂₋ₓTe₃ (x is a real number less than 2), etc.

Hereinafter, a precursor (source) for forming the chalcogenide is described in more detail.

For example, to form BiₓTe_{y} (1.5≤x≤2.5, 2.4≤y≤3.6), tellurium dioxide (TeO₂), which is a precursor of tellurium, a bismuth-based salt or bismuth-based alkoxide, such as Bi(NO₃)₃.5H₂O, which is a precursor of bismuth (Bi), and the like may be used.

For example, to form BiₓSe_{y} (1.5≤x≤2.5, 2.4≤y≤3.6), selenium dioxide (SeO₂), which is a precursor of selenium, a bismuth-based salt or bismuth-based alkoxide, such as Bi(NO₃)₃.5H₂O, which is a precursor of bismuth (Bi), and the like may be used.

For example, to form SbₓTe_{y} (1.5≤x≤2.5, 2.4≤y≤3.6), tellurium dioxide (TeO₂), which is a precursor of tellurium, an antimony-based salt or antimony-based alkoxide, such as Sb₂O₃, which is a precursor of antimony (Sb), and the like may be used.

For example, to form CdTe, tellurium dioxide (TeO₂), which is a precursor of tellurium, a cadmium-based salt or cadmium-based alkoxide, which is a precursor of cadmium (Cd), and the like may be used.

For example, to form ZnTe, tellurium dioxide (TeO₂), which is a precursor of tellurium, a zinc-based salt or zinc-based alkoxide, which is a precursor of zinc (Zn), and the like may be used.

For example, to form PbTe, tellurium dioxide (TeO₂), which is a precursor of tellurium, a lead-based salt or lead-based alkoxide, which is a precursor of lead (Pb), and the like may be used.

For example, to form Ag₂Te, tellurium dioxide (TeO₂), which is a precursor of tellurium, a silver-based salt or silver-based alkoxide, which is a precursor of silver (Ag), and the like may be used.

The P-type and N-type thermoelectric thin films 130a and 130b are preferably formed to a thickness of 0.5 to 50 μm.

The electrodes 140 is formed on the P-type and N-type thermoelectric thin films 130a and 130b. The electrodes 140 is preferably formed by electroplating one or more metal types selected from the group consisting of gold (Au), silver (Ag), and copper (Cu). Here, the electroplating may be accomplished by applying current to a two-electrode system by means of a rectifier while stirring with a magnetic bar.

The electrode wires 150 are formed to be electrically connected to the electrodes 140. The electrode wires 150 may also be electrically connected to the seed layers 120 so as to evaluate the characteristics of a thermochemical gas sensor. The electrode wires 150 may be formed of a conductive copper wire, for example, using silver paste.

The catalyst layer 170, which causes an exothermic reaction when in contact with gas to be sensed, is formed on the electrodes 140. The catalyst layer 170 is preferably formed to a thickness of 0.5 to 100 μm. The catalyst layer 170 is formed of a material including one or more metal types selected from the group consisting of platinum (Pt) and palladium (Pd). In addition, the catalyst layer 170 may be formed of a composite of one or more materials selected from the group consisting of γ-alumina, graphene, carbon nanotubes, active carbon, and carbon black and a material including one or more metal types selected from the group consisting of platinum (Pt) and palladium (Pd). For example, the composite may be a porous platinum-alumina composite including 0.1 to 12% by volume of platinum (Pt) and 88 to 99.9% by volume of alumina in consideration of an exothermic reaction with gas to be sensed. As another example, the composite may be a porous palladium-alumina composite including 0.1 to 12% by volume of palladium (Pd) and 88 to 99.9% by volume of alumina in consideration of an exothermic reaction with gas to be sensed. The catalyst layer 170 may be formed by applying a paste including a material including one or more metal types selected from the group consisting of platinum (Pt) and palladium (Pd), or a paste including a composite of one or more materials selected from the group consisting of γ-alumina, graphene, carbon nanotubes, active carbon, and carbon black and a material including one or more metal types selected from the group consisting of platinum (Pt) and palladium (Pd) onto the electrodes 140.

Before the step of forming the catalyst layer 170, the thermal grease layer 160 for transferring heat may be formed on the electrodes 140. The thermal grease layer 160 is formed to uniformly transfer heat, which is generated due to a catalyst, to the entire sensor. The thermal grease layer 160 may include a thermally conductive material such as boron nitride (BN), graphene, carbon nanotubes, active carbon, carbon black, or a mixture thereof. The thermal grease layer 160 may be formed by applying a paste, which includes a thermally conductive material such as boron nitride (BN), graphene, carbon nanotubes, active carbon, carbon black, or a mixture thereof, onto the electrodes 140.

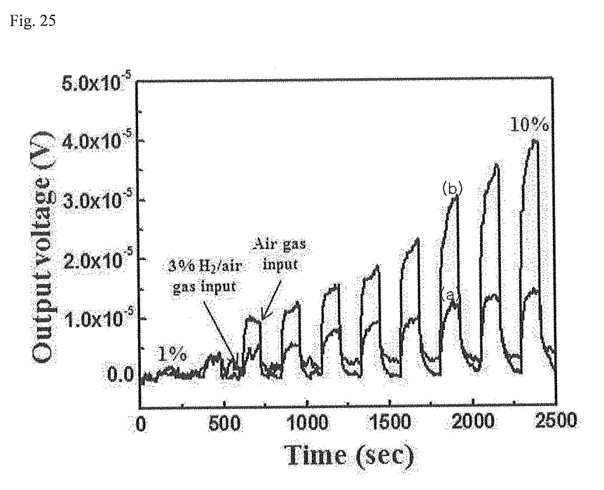

Thermoelectric properties of a device may be maximized through an N-P junction formed by forming the electrodes 140 on the P-type and N-type thermoelectric thin films 130a and 130b. In addition, as described below referring to FIG. 25, an N-P junction-type thermochemical gas sensor is advantageous in that an electromotive force can be increased compared to a single-type thermochemical gas sensor.

By this method, the P-type and N-type thermoelectric thin films 130a and 130b exhibiting thermoelectric properties in a suitable temperature range may be easily synthesized depending upon an operation temperature. In addition, various desired gas types may be sensed through a change in a catalyst reacting selectively with gas to be sensed. Further, a method of evaluating a thermoelectric performance index with gas can be utilized using a technology of sensing changes in temperature and a minute electromotive force exhibited upon sensing of gas.

Hereinafter, experimental examples according to the present invention are described in detail, but the scope of the present invention is not limited thereto.

According to the following experimental examples of the present invention, a novel thermoelectric thin film-based thermochemical gas sensor was manufactured by using a silicon wafer, on which an oxide film was formed, as a matrix of a device, forming a gold seed layers on the oxide film, selectively plating a thermoelectric thin film (thermoelectric material) on the seed layers using a wet electrolytic deposition method, and applying a paste including a catalyst (Pt/γ-alumina catalyst) capable of sensing hydrogen or a different type of gas onto the thermoelectric thin film. A catalyst layer was formed by applying a paste including Pt/γ-Al₂O₃ after selectively plating a thermoelectric thin film formed of Bi₂Te₃ or Sb₂Te₃, which is a chalcogenide known as a thermoelectric material, using a wet electrolytic deposition method. Bi₂Te₃ and Sb₂Te₃, which exhibit high thermoelectric properties at room temperature, may be easily synthesized using a wet electrolytic deposition method.

### EXPERIMENTAL EXAMPLE 1

A silicon wafer having a thickness of 500 μm, a width of 2.5 cm, and a length of 2.5 cm was used as a substrate. An oxide layer was formed on the silicon wafer.

To manufacture a single-type thermoelectric device on the silicon wafer, a gold seed layer was formed on the silicon wafer, on which an oxide layer has been formed, through an electron beam (E-beam). The thickness (height) of the formed seed layer was about 200 nm.

To find optimal conditions for thermoelectric thin film formation, a reduction potential under each condition was measured using cyclic voltammetry. The seed layer was electroplated while applying a voltage of 50 mV for one hour using a three-electrode system by means of a constant rectifier. Electrolytes used for the electroplating were prepared by adding 0 mM, 10 mM, and 40 mM of Bi(NO₃)₃.5H₂O to a solution composed of 1 M of HNO₃, 0.5 M of C₄H₆O₆, and 10 mM of TeO₂ to vary the concentration of Bi³⁺.

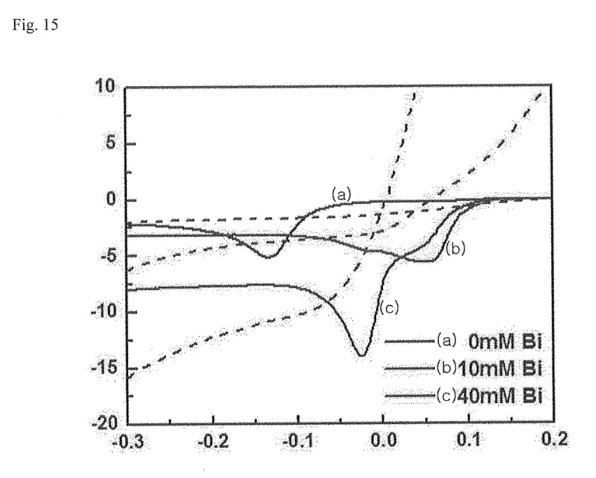

FIG. 15 illustrates results of Bi³⁺ concentration-dependent reduction potentials measured using cyclic voltammetry. In the cyclic voltammetry, Ag/AgCl (sat. KCl) was used as a counter electrode, and a scan rate was 10 mV/s.

In FIG. 15, dotted lines represent oxidation slopes in 1 M HNO₃ and 0.5 M C₄H₆O₆, full lines represent reduction slopes in 1 M HNO₃ and 0.5 M C₄H₆O₆, (a) represents a cyclic voltammogram at a Bi³⁺ concentration of 0 mM, (b) represents a cyclic voltammogram at a Bi³⁺ concentration of 10 mM, and (c) represents a cyclic voltammogram at a Bi³⁺ concentration of 40 mM.

### EXPERIMENTAL EXAMPLE 2

A silicon wafer having a thickness of 500 μm, a width of 2.5 cm, and a length of 2.5 cm was used as a substrate. An oxide layer was formed on the silicon wafer.

To manufacture a single-type thermoelectric device on the silicon wafer, a gold seed layer was formed on the silicon wafer, on which an oxide layer has been formed, through an electron beam (E-beam). The thickness (height) of the formed seed layer was about 200 nm.

Wet electrolytic deposition was performed on the seed layer while applying a voltage for one hour in a three-electrode system by means of a constant rectifier. Electrolytes used for the wet electrolytic deposition were prepared by adding 10 mM of Bi(NO₃)₃.5H₂O to a solution composed of 1 M of HNO₃ and 10 mM of TeO₂.

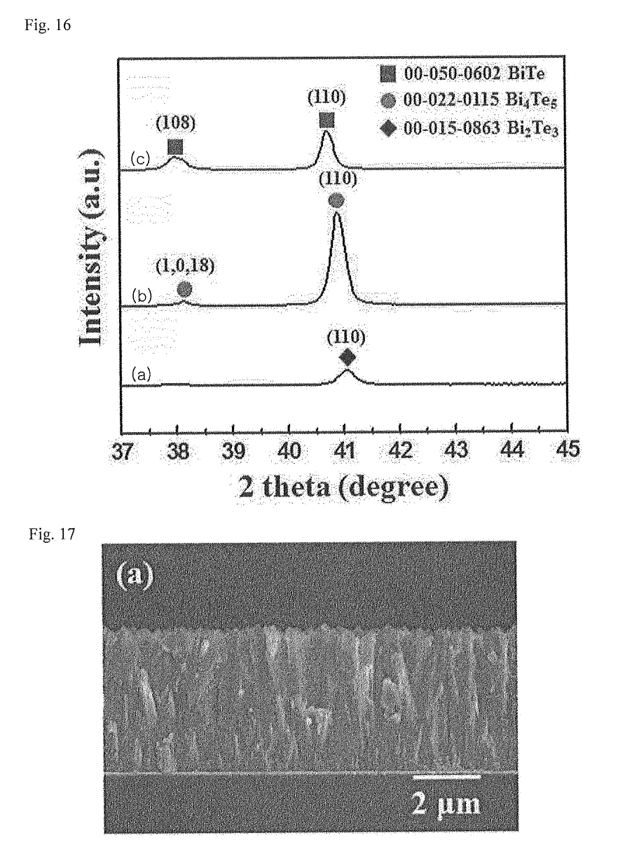

FIG. 16 illustrates analysis results of X-ray diffraction (XRD) patterns obtained after depositing while varying an applied voltage during wet electrolytic deposition so as to produce a Bi₂Te₃ phase, which exhibits the highest thermoelectric properties, among BiₓTe_{y} phases. In FIG. 16, (a) illustrates a case wherein a voltage of 50 mV is applied, and (b) illustrates a case wherein a voltage of 0 mV is applied, and (c) illustrates a case wherein a voltage of −50 mV is applied.

Referring to FIG. 16, it can be confirmed from the XRD analysis results that a Bi₂Te₃ (JCPDS No. 00-015-0863) phase is synthesized when a voltage of 50 mV is applied, a Bi₄Te₅ (JCPDS No. 00-022-0115) phase is synthesized when a voltage of 0 mV is applied, and a BiTe (JCPDS No. 00-050-0602) phase is synthesized when a voltage of −50 mV is applied. Therefore, it can be confirmed that an applied voltage suitable for obtaining the Bi₂Te₃ phase is 50 mV.

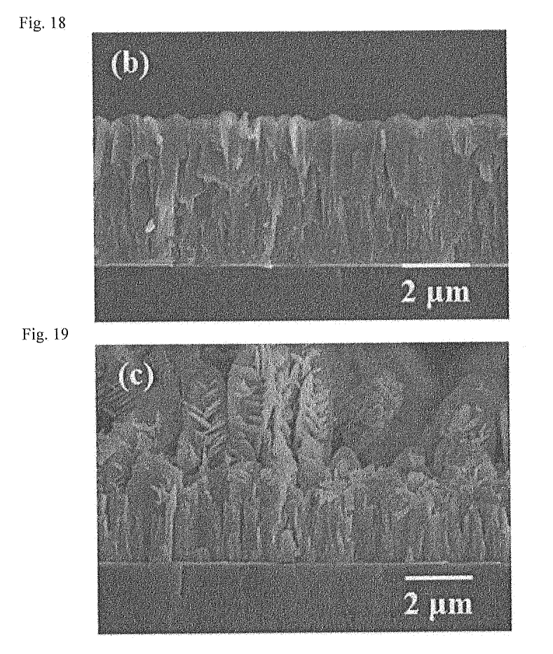

FIG. 17 illustrates a field emission scanning electron microscope (FE-SEM) image of a BiₓTe_{y} thin film deposited by applying a voltage of 50 mV for one hour in a wet electrolytic deposition method, FIG. 18 illustrates a FE-SEM image of a BiₓTe_{y} thin film deposited by applying a voltage of 0 mV for one hour in a wet electrolytic deposition method, and FIG. 19 illustrates a FE-SEM image of a BiₓTe_{y} thin film deposited by applying a voltage of −50 mV for one hour on a wafer in a wet electrolytic deposition method.

Referring to FIGS. 17 to 19, it can be confirmed that the BiₓTe_{y} thin film grows to a thickness of 4.28 μm per hour on average.

### EXPERIMENTAL EXAMPLE 3

A silicon wafer having a thickness of 500 μm, a width of 2.5 cm, and a length of 2.5 cm was used as a substrate. An oxide layer was formed on the silicon wafer.

To manufacture a single-type thermoelectric device on the silicon wafer, a gold seed layer was formed on the silicon wafer, on which an oxide layer has been formed, through an electron beam (E-beam). The thickness (height) of the formed seed layer was about 200 nm.

To find optimal conditions for thermoelectric thin film formation, a reduction potential under each condition was measured using cyclic voltammetry. The seed layer was electroplated while applying a voltage of −175 mV for one hour using a three-electrode system by means of a constant rectifier. Electrolytes used for the electroplating were prepared by adding 3 mM and 9 mM of Sb₂O₃ to a solution composed of 1 M of HNO₃, 0.5 M of C₄H₆O₆, and 9 mM of TeO₂ to vary the concentration of Sb³⁺.

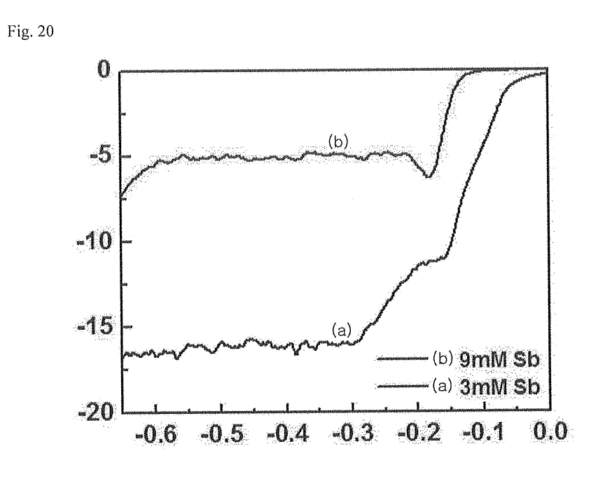

FIG. 20 illustrates results of Sb³⁺ concentration-dependent reduction potentials measured using cyclic voltammetry. In the cyclic voltammetry, Ag/AgCl (sat. KCl) was used as a counter electrode, and a scan rate was 10 mV/s.

In FIG. 20, (a) illustrates a cyclic voltammogram when 3 mM of Sb³⁺ and 9 mM of HTeO₂⁺ are included in a solution composed of 1 M of HNO₃ and 0.5 M of C₄H₆O₆, and (b) illustrates a cyclic voltammogram when 9 mM of Sb³⁺ and 9 mM of HTeO₂⁺ are included in a solution composed of 1 M of HNO₃ and 0.5 M of C₄H₆O₆.

### EXPERIMENTAL EXAMPLE 4

A silicon wafer having a thickness of 500 μm, a width of 2.5 cm, and a length of 2.5 cm was used as a substrate. An oxide layer was formed on the silicon wafer.

To manufacture a single-type thermoelectric device on the silicon wafer, a gold seed layer was formed on the silicon wafer, on which an oxide layer has been formed, through an electron beam (E-beam). The thickness (height) of the formed seed layer was about 200 nm.

Wet electrolytic deposition was performed on the seed layer while applying a voltage for one hour in a three-electrode system by means of a constant rectifier. Electrolytes used for the wet electrolytic deposition were prepared by adding 9 mM of Sb₂O₃ to a solution composed of 1 M of HNO₃, 0.5 M of C₄H₆O₆, and 9 mM of TeO₂.

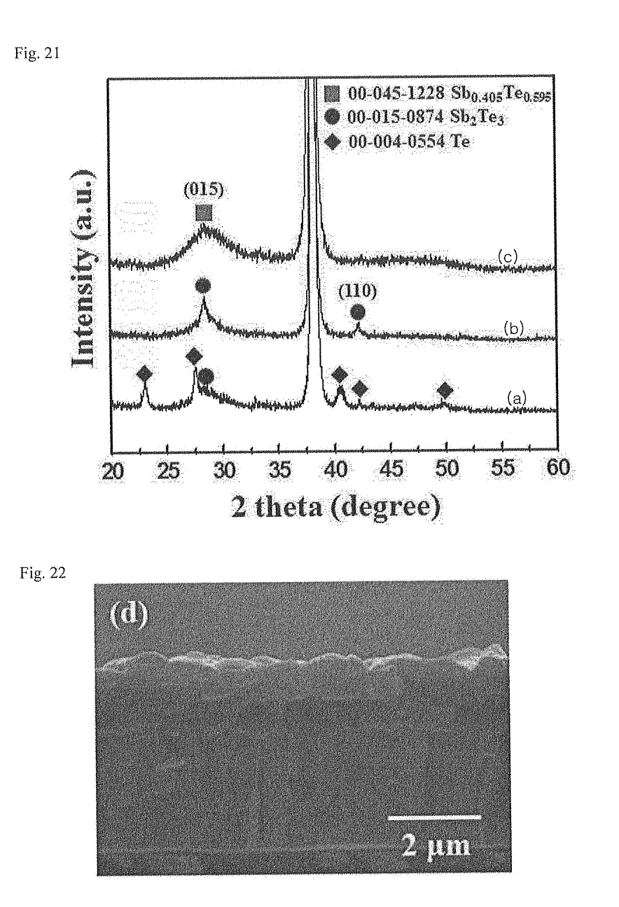

FIG. 21 illustrates analysis results of X-ray diffraction (XRD) patterns obtained after depositing while varying an applied voltage during wet electrolytic deposition so as to produce a Sb₂Te₃ phase, which exhibits the highest thermoelectric properties, among SbₓTe_{y} phases. In FIG. 21, (a) illustrates a case wherein a voltage of −150 mV is applied, and (b) illustrates a case wherein a voltage of −175 mV is applied, and (c) illustrates a case wherein a voltage of −200 mV is applied.

Referring to FIG. 21, it can be confirmed from the XRD analysis results that a Te (JCPDS No. 00-004-0554) phase and a Sb₂Te₃ (JCPDS No. 00-015-0874) phase are synthesized together when a voltage of −150 mV is applied, a Sb₂Te₃ (JCPDS No. 00-015-0874) phase is synthesized when a voltage of −175 mV is applied, and a Sb_{0.405}Te_{0.595}(JCPDS No. 00-045-1228) phase is synthesized when a voltage of −200 mV is applied. Therefore, it can be confirmed that an applied voltage suitable for obtaining the Sb₂Te₃ phase is −175 mV.

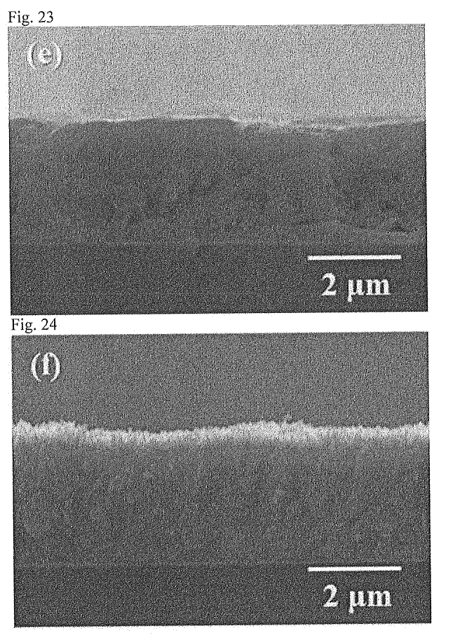

FIG. 22 illustrates a FE-SEM image of a SbₓTe_{y} thin film deposited by applying a voltage of −150 mV for one hour on a wafer in a wet electrolytic deposition method, FIG. 23 illustrates a FE-SEM image of a SbₓTe_{y} thin film deposited by applying a voltage of −175 mV for one hour on a wafer in a wet electrolytic deposition method, and FIG. 24 illustrates a FE-SEM image of a SbₓTe_{y} thin film deposited by applying a voltage of −200 mV for one hour on a wafer in a wet electrolytic deposition method.

Referring to FIGS. 22 to 24, it can be confirmed that the SbₓTe_{y} thin film grows to a thickness of 2.68 μm per hour on average.

### EXPERIMENTAL EXAMPLE 5

To manufacture a single-type thermochemical gas sensor based on a single-type thermoelectric thin film, a silicon wafer having a thickness of 500 μm, a width of 2.5 cm, and a length of 2.5 cm was used as a substrate. An oxide layer was formed on the silicon wafer.

The thin film was masked, except for a portion to be plated, using a stencil. Subsequently, the exposed portion was subjected to an electron beam (E-beam) process, thereby forming a gold seed layer. The thickness (height) of the finally formed seed layer was about 200 nm.

A Bi₂Te₃ thermoelectric thin film was selectively formed on the seed layer using a wet electrolytic deposition method. To synthesize the Bi₂Te₃ thin film, wet electrolytic deposition for forming the Bi₂Te₃ thin film was performed while applying a voltage of 50 mV for one hour in a three-electrode system using a three-electrode constant rectifier. An electrolyte used for forming the Bi₂Te₃ thin film was prepared by mixing 1 M of HNO₃, 10 mM of Bi(NO₃)₃.5H₂O, and 10 mM of TeO₂.

An electrode was formed on the thermoelectric Bi₂Te₃ thin film. The electrode was manufactured using a system for electroplating gold. Electroplating for forming the electrode was performed while applying 1 mA of a current in a two-electrode system using a constant rectifier.

A conductive copper wire was connected to the electrode using a silver paste so as to connect to a nanovoltmeter for measuring an electromotive force generated in a thermoelectric device before hydrogen sensing.

To uniformly transfer heat generated due to a catalyst to the entire sensor, thermal grease for transferring heat was applied onto the electrode to form a thermal grease layer. As the thermal grease, a paste prepared by dispersing boron nitride (BN) in water and ethanol was used.

A catalyst layer was formed on the thermal grease layer. The catalyst layer was formed by directly applying 0.25 ml of a 2 vol % meso-porous Pt/alumina catalyst paste onto the thermal grease layer. For more uniform heat transfer, a catalyst paste was uniformly spread and applied onto the thermal grease layer. As the catalyst paste, a paste prepared by dispersing a Pt/γ-Al₂O₃ catalyst in a mixture of water and ethanol was used.

### EXPERIMENTAL EXAMPLE 6

To manufacture an N-P junction-type thermochemical gas sensor using a P-type thermoelectric thin film and an N-type thermoelectric thin film, a silicon wafer having a thickness of 500 μm, a width of 2.5 cm, and a length of 2.5 cm was used as a substrate. An oxide layer was formed on the silicon wafer.

The thin film was masked, except for a portion to be plated, using a stencil. Subsequently, the exposed portion was subjected to an electron beam (E-beam) process, thereby forming gold seed layers. The thickness (height) of the finally formed seed layers was about 200 nm.

A Bi₂Te₃ thermoelectric thin film and a Sb₂Te₃ thermoelectric thin film were selectively formed on the seed layers using a wet electrolytic deposition method. First, to synthesize the Sb₂Te₃ thin film, a portion on which the Bi₂Te₃ thin film was to be synthesized was masked using Miccrostop, and wet electrolytic deposition for forming the Sb₂Te₃ thin film was performed while applying a voltage of −175 mV for one hour in a three-electrode system. An electrolyte for forming the Sb₂Te₃ thin film was prepared by mixing 1 M of HNO₃, 3 mM of Sb₂O₃, 9 mM of TeO₂, and 0.5 M of C₄H₆O₆. Next, to synthesize the Bi₂Te₃ thin film, the portion on which the Sb₂Te₃ thin film had been synthesized was masked using Miccrostop, and wet electrolytic deposition for forming the Bi₂Te₃ thin film was performed while applying a voltage of 50 mV for one hour in a three-electrode system using a three-electrode constant rectifier. An electrolyte forming the Bi₂Te₃ thin film was prepared by mixing 1 M of HNO₃, 10 mM of Bi(NO₃)₃. 5H₂O, and 10 mM of TeO₂.

Electrodes ware formed on the Bi₂Te₃ thermoelectric thin film and the Sb₂Te₃ thermoelectric thin film. The electrodes were manufactured by a system for electroplating gold. Electroplating for forming the electrodes was performed while applying 1 mA of a current in a two-electrode system using a constant rectifier.

A conductive copper wire was connected to the electrodes using a silver paste so as to connect to a nanovoltmeter for measuring an electromotive force generated in a thermoelectric device before hydrogen sensing.

To uniformly transfer heat generated due to a catalyst to the entire sensor, thermal grease for transferring heat was applied on the electrodes to form a thermal grease layer. As the thermal grease, a paste prepared by dispersing boron nitride (BN) in water and ethanol was used.

A catalyst layer was formed on the thermal grease layer. The catalyst layer was formed by directly applying 0.25 ml of a 2 vol % meso-porous Pt/alumina catalyst paste onto the thermal grease layer. For more uniform heat transfer, a catalyst paste was uniformly spread and applied onto the thermal grease layer. As the catalyst paste, a paste prepared by dispersing a Pt/γ-Al₂O₃ catalyst in a mixture of water and ethanol was used.

Hydrogen sensing characteristics of the single-type thermochemical gas sensor manufactured according to Experimental Example 5 and the N-P junction-type thermochemical gas sensor manufactured according to Experimental Example 6 were evaluated. To evaluate the sensing characteristics, a process in which a hydrogen gas was flowed for 120 sec and the flowing was shut off for 120 sec was repeated.

FIG. 25 illustrates hydrogen concentration-dependent electromotive force changes in a device when hydrogen is sensed using single-type and n-p junction-type thermochemical gas sensors. In FIG. 25, (a) illustrates a result of the single-type thermochemical gas sensor manufactured according to Experimental Example 5, and (b) illustrates a result of the n-p junction-type thermochemical gas sensor manufactured according to Experimental Example 6.

Referring to FIG. 25, it can be confirmed that the electromotive force increases with an increasing hydrogen concentration. When 10 vol % hydrogen, as a highest concentration condition, was flowed, a maximum electromotive force of 13.97 μV was generated in the single-type thermochemical gas sensor and a maximum electromotive force of 39.19 μV was generated in the n-p junction-type thermochemical gas sensor. The electromotive force which was generated in the n-p junction-type thermochemical gas sensor was about 2.8 times higher than that in the single-type thermochemical gas sensor.

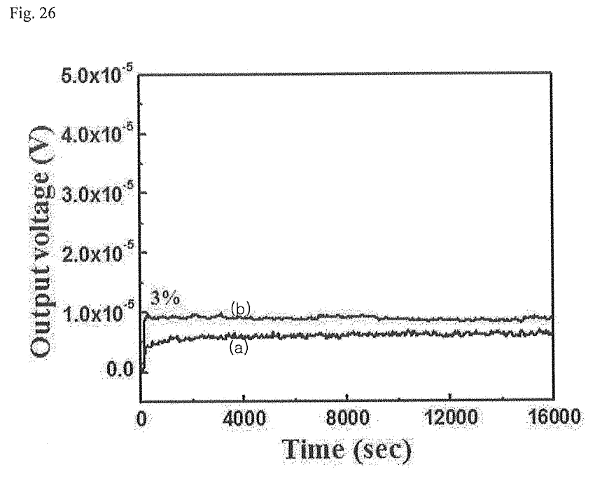

FIG. 26 illustrates time-dependent electromotive force changes under a condition that 3 vol % hydrogen flows so as to measure the reliability of single-type and n-p junction-type thermochemical gas sensors. In FIG. 26, (a) illustrates a result of the single-type thermochemical gas sensor manufactured according to Experimental Example 5, and (b) illustrated a result of the n-p junction-type thermochemical gas sensor manufactured according to Experimental Example 6.

Referring to FIG. 26, it can be confirmed that an electromotive force of 95% or more with respect to an initial electromotive force is maintained for four hours, and the electromotive force is maintained without any significant change even after prolonged exposure.

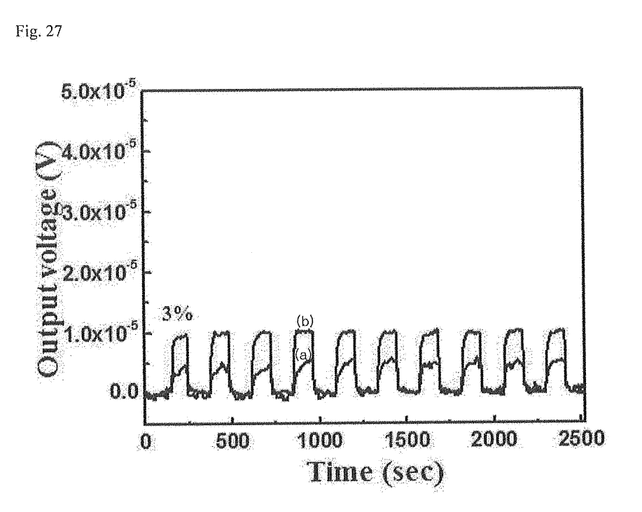

FIG. 27 illustrates changes in an electromotive force when 3 vol % hydrogen and dry air are alternately, repeatedly flowed 10 times to measure the repeatability of the single-type and n-p junction-type thermochemical gas sensors. In FIG. 27, (a) illustrates a result of the single-type thermochemical gas sensor manufactured according to Experimental Example 5, and (b) illustrates a result of the n-p junction-type thermochemical gas sensor manufactured according to Experimental Example 6.

Referring to FIG. 27, changes in the electromotive force are within 5% even if 3 vol % hydrogen and dry air are repeatedly flowed. Therefore, it can be confirmed that the electromotive force is not greatly changed although the sensors are repeatedly exposed to hydrogen.

Although the present invention has been described through preferred embodiments, the present invention is not intended to be limited to the embodiments. Those skilled in the art will appreciate that various modifications, additions and substitutions are possible, without departing from the scope and spirit of the invention.

### INDUSTRIAL APPLICABILITY

A thermochemical gas sensor according to the present invention can be miniaturized and manufactured based on a thermoelectric thin film, thereby providing a broad concentration range for sensing gas. Accordingly, the thermochemical gas sensor is industrially applicable.

1. A thermochemical gas sensor, comprising:
a substrate provided with an insulating layer;
a seed layer provided on the insulating layer;
a thermoelectric thin film provided on the seed layer;
an electrode provided on the thermoelectric thin film;
a catalyst layer provided on the electrode and causing an exothermic reaction when in contact with gas to be sensed; and
an electrode wire electrically connected to the electrode,
wherein the thermoelectric thin film is formed of a material comprising a chalcogenide,
wherein the chalcogenide comprises one or more chalcogens selected from the group consisting of selenium (Se) and tellurium (Te).

2. A thermochemical gas sensor, comprising:
a substrate provided with an insulating layer;
seed layers provided on the insulating layer;
a P-type thermoelectric thin film provided on the seed layers;
an N-type thermoelectric thin film provided on the seed layers and spaced from the P-type thermoelectric thin film;
electrodes provided on the P-type thermoelectric thin film and the N-type thermoelectric thin film;
a catalyst layer provided on the electrodes and causing an exothermic reaction when in contact with gas to be sensed; and
electrode wires electrically connected to the electrodes,
wherein the P-type thermoelectric thin film and the N-type thermoelectric thin film are formed of a material comprising a chalcogenide,
wherein the chalcogenide comprises one or more chalcogens selected from the group consisting of selenium (Se) and tellurium (Te), and the P-type thermoelectric thin film is formed of a chalcogenide different from a chalcogenide forming the N-type thermoelectric thin film.

3. The thermochemical gas sensor according to claim 1, wherein a thermal grease layer for transferring heat is provided between the electrode and the catalyst layer.

4. The thermochemical gas sensor according to claim 3, wherein the thermal grease layer comprises one or more thermally conductive materials selected from the group consisting of boron nitride (BN), graphene, carbon nanotubes, active carbon, and carbon black.

5. The thermochemical gas sensor according to claim 1, wherein the substrate comprises a silicon (Si) substrate,
the insulating layer comprises a SiO₂ oxide film,
the seed layer has a thickness of 10 to 1000 nm and is formed of a material comprising one or more metals selected from the group consisting of gold (Au), silver (Ag), and copper (Cu).

6. The thermochemical gas sensor according to claim 1, wherein the catalyst layer is formed of a composite of one or more materials selected from the group consisting of γ-alumina, graphene, carbon nanotubes, active carbon, and carbon black and a material comprising one or more metal types selected from the group consisting of platinum (Pt) and palladium (Pd), and has a thickness of 0.5 to 100 um.

7. The thermochemical gas sensor according to claim 1, wherein the chalcogenide comprises one or more materials selected from the group consisting of BiₓSe_{y} (1.5≤x≤2.5, 2.4≤y≤3.6), SbₓSe_{y} (1.5≤x≤2.5, 2.4≤y≤3.6v), (Bi₁₋ₘSbₘ)ₓSe_{y} (0<m<1, 1.5≤x≤2.5, 2.4≤y≤3.6), PbSe, CdSe, ZnSe, PbTeSe, BiₓTe_{y} (1.5≤x≤2.5, 2.4≤y≤3.6), SbₓTe_{y} (1.5≤x≤2.5, 2.4≤y≤3.6), (Bi₁₋ₘSbₘ)ₓTe_{y} (0<m<1, 1.5≤x≤2.5, 2.4≤y≤3.6), PbTe, CdTe, ZnTe, La₃Te₄, AgSbTe₂, Ag₂Te, AgPb₁₈BiTe₂₀, (GeTe)ₓ(AgSbTe₂)₁₋ₓ (x is a real number less than 1), AgₓPb₁₈SbTe₂₀ (x is a real number less than 1), AgₓPb_{22.5}SbTe₂₀ (x is a real number less than 1), SbₓTe₂₀ (x is a real number less than 1), and BiₓSb₂₋ₓTe₃ (x is a real number less than 2).

8. A method of manufacturing a thermochemical gas sensor, the method comprising:
a step of preparing a substrate provided with an insulating layer;
a step of forming a seed layer on the insulating layer;
a step of forming a thermoelectric thin film on the seed layer using a wet electrolytic deposition method;
a step of forming an electrode on the thermoelectric thin film;
a step of forming an electrode wire electrically connected to the electrode; and
a step of forming a catalyst layer, which causes an exothermic reaction when in contact with gas to be sensed, on the electrode,
wherein the thermoelectric thin film is formed of a material comprising a chalcogenide,
wherein the chalcogenide comprises one or more chalcogens selected from the group consisting of selenium (Se) and tellurium (Te).

9. A method of manufacturing a thermochemical gas sensor, the method comprising:
a step of preparing a substrate provided with an insulating layer;
a step of forming seed layers on the insulating layer;
a step of forming a P-type thermoelectric thin film and an N-type thermoelectric thin film to be spaced from each other on the seed layers using a wet electrolytic deposition method;
a step of forming electrodes on the P-type thermoelectric thin film and the N-type thermoelectric thin film;
a step of forming electrode wires electrically connected to the electrodes; and
a step of forming a catalyst layer, which causes an exothermic reaction when in contact with gas to be sensed, on the electrodes,
wherein the thermoelectric thin film is formed of a material comprising a chalcogenide,
wherein the chalcogenide comprises one or more chalcogens selected from the group consisting of selenium (Se) and tellurium (Te), and the P-type thermoelectric thin film is formed of a chalcogenide different from a chalcogenide forming the N-type thermoelectric thin film.

10. The method according to claim 8, further comprising, before the step of forming the catalyst layer, a step of forming a thermal grease layer for transferring heat on the electrode.

11. The method according to claim 10, wherein the thermal grease layer comprises one or more thermally conductive materials selected from the group consisting of boron nitride (BN), graphene, carbon nanotubes, active carbon, and carbon black.

12. The method according to claim 8, wherein the substrate comprises a silicon (Si) substrate,
the insulating layer comprises a SiO₂ oxide film,
the seed layer has a thickness of 10 to 1000 nm and is formed of a material comprising one or more metal types selected from the group consisting of gold (Au), silver (Ag), and copper (Cu).

13. The method according to claim 8, wherein the catalyst layer is formed of a composite of one or more materials selected from the group consisting of γ-alumina, graphene, carbon nanotubes, active carbon, and carbon black and a material comprising one or more metal types selected from the group consisting of platinum (Pt) and palladium (Pd), and has a thickness of 0.5 to 100 μm.

14. The method according to claim 8, wherein the chalcogenide comprises one or more materials selected from the group consisting of BiₓSe_{y} (1.5≤x≤2.5, 2.4≤y≤3.6), SbₓSe_{y} (1.5≤x≤2.5, 2.4≤y≤3.6), (Bi₁₋ₘSbₘ)ₓSe_{y} (0<m<1, 1.5≤x≤2.5, 2.4≤y≤3.6), PbSe, CdSe, ZnSe, PbTeSe, BiₓTe_{y} (1.5≤x≤2.5, 2.4≤y≤3.6), SbₓTe_{y} (1.5≤x≤2.5, 2.4≤y≤3.6v), (Bi₁₋ₘSbₘ)ₓTe_{y} (0<m<1, 1.5≤x≤2.5, 2.4≤y≤3.6), PbTe, CdTe, ZnTe, La₃Te₄, AgSbTe₂, Ag₂Te, AgPb₁₈BiTe₂₀, (GeTe)ₓ(AgSbTe₂)₁₋ₓ (x is a real number less than 1), AgₓPb₁₈SbTe₂₀ (x is a real number less than 1), AgₓPb_{22.5}SbTe₂₀ (x is a real number less than 1), SbₓTe₂₀ (x is a real number less than 1), and BiₓSb₂₋ₓTe₃ (x is a real number less than 2).
